(19) United States
(12) Patent Application Publication
(10) Pub. No.: US 2024/0234651 A1
(43) Pub. Date: Jul. 11, 2024

(54) DISPLAY DEVICE AND METHOD OF FABRICATING THE SAME

(71) Applicant: Samsung Display Co., LTD., Yongin-si (KR)

(72) Inventors: Won Je JO, Yongin-si (KR); Che Ho LEE, Yongin-si (KR)

(21) Appl. No.: 18/242,135

(22) Filed: Sep. 5, 2023

(30) Foreign Application Priority Data
Jan. 9, 2023 (KR) 10-2023-0002985

(51) Int. Cl. H01L 33/56; H01L 25/075; H01L 25/16

(52) U.S. Cl. CPC H01L 33/56; H01L 25/0753; H01L 25/167; H01L 2933/005

(57) ABSTRACT

A display device including a substrate having a front portion, a first side portion, a second side portion, and a corner portion disposed between the first side portion and the second side portion, a plurality of light emitting elements disposed on the front portion and the corner portion and each of the plurality of light emitting elements including a first electrode, a light emitting layer and a second electrode, a first encapsulating inorganic layer disposed on the second electrode and the corner portion, a first encapsulating organic layer disposed on the first encapsulating inorganic layer and the corner portion, a second encapsulating inorganic layer disposed on the first encapsulating organic layer and the corner portion, and a second encapsulating organic layer disposed between the second electrode and the first encapsulating inorganic layer.

This application claims priority to Korean Patent Application No. 10-2023-0002985, filed on Jan. 9, 2023, and all the benefits accruing therefrom under 35 U.S.C. § 119, the content of which in its entirety is herein incorporated by reference.

### BACKGROUND

### 1. Field

The disclosure relates to a display device and a method of fabricating the same.

### 2. Description of the Related Art

As the information society develops, demands for display devices for displaying images are increasing in various forms. For example, display devices are applied to various electronic devices such as smartphones, digital cameras, notebook computers, navigation devices, and smart televisions.

The display devices may be flat panel display devices such as liquid crystal display devices, field emission display devices, and light emitting display devices. The light emitting display devices include an organic light emitting display device including an organic light emitting element, an inorganic light emitting display device including an inorganic light emitting element such as an inorganic semiconductor, and a micro-light emitting display device including a micro-light emitting element.

As display devices are applied to various electronic devices, display devices having various designs are required. For example, when a display device is a light emitting display device, it may display an image not only on a front portion but also on a side portion bent at each of four edges of the front portion. For example, the display device may include a corner portion disposed between a first side portion bent at a first edge of the front portion and a second side portion bent at a second edge of the front portion.

### SUMMARY

Embodiments of the invention provide a display device including an encapsulation structure that can reduce the strain applied to a corner portion and a method of fabricating the display device.

An embodiment of the invention provides a display device including a substrate having a front portion, a first side portion extending from a first side of the front portion, a second side portion extending from a second side of the front portion, and a corner portion disposed between the first side portion and the second side portion, a plurality of light emitting elements disposed on the front portion and the corner portion of the substrate and each of the plurality of light emitting elements including a first electrode, a light emitting layer and a second electrode, a first encapsulating inorganic layer disposed on the second electrode of each of the plurality of light emitting elements on the front portion of the substrate and the corner portion of the substrate, a first encapsulating organic layer disposed on the first encapsulating inorganic layer on the front portion of the substrate and the corner portion of the substrate, a second encapsulating inorganic layer disposed on the first encapsulating organic layer on the front portion of the substrate and the corner portion of the substrate, and a second encapsulating organic layer disposed between the second electrode of each of the plurality of light emitting elements and the first encapsulating inorganic layer on the corner portion of the substrate.

In an embodiment, a modulus of the second encapsulating organic layer may be lower than a modulus of the first encapsulating inorganic layer.

In an embodiment, the first encapsulating organic layer may include a monomer, and the second encapsulating organic layer may include hexamethyldisiloxane (HMDSO). In an embodiment, a wrinkle portion may be formed on the corner portion of the substrate due to a difference between the modulus of the second encapsulating organic layer and the modulus of the first encapsulating inorganic layer.

In an embodiment, the display device may further include a third encapsulating organic layer disposed between the first encapsulating organic layer and the second encapsulating inorganic layer on the corner portion of the substrate.

In an embodiment, a modulus of the third encapsulating organic layer may be lower than the modulus of the second encapsulating inorganic layer.

In an embodiment, the third encapsulating organic layer may be made of the same material as the second encapsulating organic layer.

In an embodiment, the third encapsulating organic layer may include hexamethyldisiloxane (HMDSO).

In an embodiment, a wrinkle portion may be formed on the corner portion of the substrate due to a difference between the modulus of the third encapsulating organic layer and the modulus of the second encapsulating inorganic layer.

An embodiment of the invention provides a display device including a substrate having a front portion, a first side portion extending from a first side of the front portion, a second side portion extending from a second side of the front portion, and a corner portion disposed between the first side portion and the second side portion, a plurality of light emitting elements disposed on the front portion and the corner portion of the substrate and each of the plurality of light emitting elements including a first electrode, a light emitting layer and a second electrode, a first encapsulating inorganic layer disposed on the second electrode of each of the plurality of light emitting elements on the front portion of the substrate and the corner portion of the substrate, a first encapsulating organic layer disposed on the first encapsulating inorganic layer on the front portion of the substrate and the corner portion of the substrate, a second encapsulating inorganic layer disposed on the first encapsulating organic layer on the front portion of the substrate and the corner portion of the substrate, and a second encapsulating organic layer disposed between the first encapsulating organic layer and the second encapsulating inorganic layer on the corner portion of the substrate.

In an embodiment, a modulus of the second encapsulating organic layer may be lower than a modulus of the second encapsulating inorganic layer.

In an embodiment, the second encapsulating organic layer may include hexamethyldisiloxane (HMDSO).

In an embodiment, a wrinkle portion may be formed on the corner portion of the substrate due to a difference between the modulus of the second encapsulating organic layer and the modulus of the second encapsulating inorganic layer.

An embodiment of the invention provides a method of fabricating a display device, wherein the method includes forming a thin-film transistor layer including thin-film transistors on a front portion and a corner portion of a substrate among the front portion of the substrate, a first side portion extending from a first side of the front portion, a second side portion extending from a second side of the front portion, and the corner portion disposed between the first side portion and the second side portion, forming a light emitting element layer disposed on the thin-film transistor layer of the front portion and the corner portion of the substrate and including a plurality of light emitting elements, forming a second encapsulating organic layer on the light emitting element layer of the corner portion of the substrate, forming a first encapsulating inorganic layer on the light emitting element layer of the front portion of the substrate and on the second encapsulating organic layer of the corner portion of the substrate, and forming a first encapsulating organic layer on the first encapsulating inorganic layer of the front portion and the corner portion of the substrate. A modulus of the second encapsulating organic layer is lower than a modulus of the first encapsulating inorganic layer.

In an embodiment, the first encapsulating organic layer includes a monomer, and the second encapsulating organic layer includes hexamethyldisiloxane (HMDSO).

In an embodiment, the method may further include forming a third encapsulating organic layer on the first encapsulating organic layer of the corner portion of the substrate, and forming a second encapsulating inorganic layer on the first encapsulating organic layer of the front portion of the substrate and on the third encapsulating organic layer of the corner portion of the substrate.

In an embodiment, the third encapsulating organic layer may be made of the same material as the second encapsulating organic layer.

In an embodiment, a modulus of the third encapsulating organic layer is lower than the modulus of the second encapsulating inorganic layer.

In an embodiment, the third encapsulating organic layer includes hexamethyldisiloxane (HMDSO).

In an embodiment, the method may further include forming a touch electrode layer including touch electrodes on the second encapsulating inorganic layer of the front portion and the corner portion of the substrate.

In an embodiment, an encapsulation layer having a wrinkle portion is formed in a plurality of corner portions which are double-curvature areas. This is because an encapsulation layer having a wrinkle portion is advantageous in stretch and compression compared with an encapsulation layer not having a wrinkle portion. Therefore, the strain of the encapsulation layer in the corner portions can be reduced.

### BRIEF DESCRIPTION OF THE DRAWINGS

These and/or other features of the invention will become apparent and more readily appreciated from the following description of the embodiments, taken in conjunction with the accompanying drawings, in which:

FIG. 1 is a perspective view of a display device according to an embodiment;

FIG. 2 is a planar view of the display device according to the embodiment;

FIG. 3 is a cross-sectional view of the display device according to the embodiment;

FIG. 4 is a layout view illustrating, in detail, first through third display areas and a non-display area disposed in a first corner portion of a display panel according to an embodiment;

FIG. 5 is a layout view of an example of the first display area of FIG. 4, according to an embodiment;

FIG. 6 is a layout view of an example of the second display area of FIG. 4, according to an embodiment;

FIG. 7 is a layout view of an example of the third display area of FIG. 4, according to an embodiment;

FIG. 8 is a cross-sectional view of an example of the display panel taken along line A-A′ of FIG. 5, according to an embodiment;

FIG. 9 is a cross-sectional view of an example of the display panel taken along line B-B′ of FIG. 6, according to an embodiment;

FIG. 10 is a cross-sectional view of an example of the display panel taken along line C-C′ of FIG. 7, according to an embodiment;

FIG. 11 shows a focused ion beam (FIB) image of a third encapsulating organic layer and a second encapsulating inorganic layer of FIG. 9, according to an embodiment;

FIG. 12 is a cross-sectional view of an example of the display panel taken along line B-B′ of FIG. 6, according to an embodiment;

FIG. 13 is a cross-sectional view of an example of the display panel taken along line C-C′ of FIG. 7, according to an embodiment;

FIG. 14 is a cross-sectional view of an example of the display panel taken along line B-B′ of FIG. 6, according to an embodiment;

FIG. 15 is a cross-sectional view of an example of the display panel taken along line C-C′ of FIG. 7, according to an embodiment;

FIG. 16 is a layout view illustrating, in detail, first through third display areas and a non-display area disposed in a first corner portion of a display panel according to an embodiment;

FIG. 17 is a layout view of an example of the second display area of FIG. 16, according to an embodiment;

FIG. 18 is a flowchart illustrating a method of fabricating a display device according to an embodiment;

FIG. 19 is a cross-sectional view for explaining the method of fabricating the display device according to an embodiment;

FIG. 20 is a cross-sectional view for explaining the method of fabricating the display device according to an embodiment;

FIG. 21 is a cross-sectional view for explaining the method of fabricating the display device according to an embodiment;

FIG. 22 is a cross-sectional view for explaining the method of fabricating the display device according to an embodiment;

FIG. 23 is a cross-sectional view for explaining the method of fabricating the display device according to an embodiment;

FIG. 24 is a cross-sectional view for explaining the method of fabricating the display device according to an embodiment;

FIG. 25 is a cross-sectional view for explaining the method of fabricating the display device according to an embodiment;

FIG. 26 is a cross-sectional view for explaining the method of fabricating the display device according to an embodiment;

FIG. 27 is a cross-sectional view for explaining the method of fabricating the display device according to an embodiment;

FIG. 28 is a cross-sectional view for explaining the method of fabricating the display device according to an embodiment;

FIG. 29 is a cross-sectional view for explaining the method of fabricating the display device according to an embodiment;

FIG. 30 is a cross-sectional view for explaining the method of fabricating the display device according to an embodiment;

FIG. 31 illustrates a display device having a wrinkle portion according to an embodiment;

FIG. 32 illustrates a display device having a wrinkle portion according to an embodiment; and

FIG. 33 illustrates a display device having a wrinkle portion according to an embodiment.

### DETAILED DESCRIPTION

Embodiments of the invention will now be described more fully hereinafter with reference to the accompanying drawings, in which preferred embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached drawing figures, the thickness of layers and regions may be exaggerated for clarity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will also be understood that when a layer is referred to as being “on” another layer or substrate, it can be directly on the other layer or substrate, or intervening layers may also be present. In contrast, when an element is referred to as being “directly on” another element, there are no intervening elements present.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” “At least one of A and B” means “A and/or B.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. A region illustrated or described as flat may, typically, have rough and/or nonlinear features, for example. Moreover, sharp angles that are illustrated may be rounded. Thus, the regions illustrated in the drawing figures are schematic in nature and their shapes are not intended to illustrate the precise shape of a region and are not intended to limit the scope of the claims.

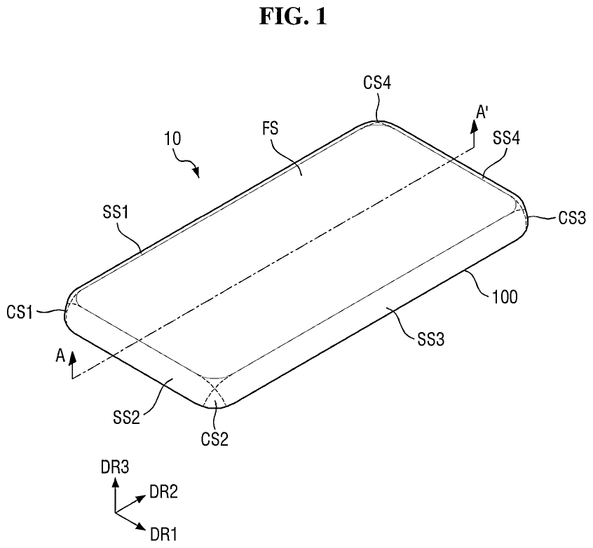

FIG. 1 is a perspective view of a display device 10 according to an embodiment.

Referring to FIG. 1, the display device 10 according to an embodiment may be applied to portable electronic devices such as mobile phones, smartphones, tablet personal computers (PCs), mobile communication terminals, electronic notebooks, electronic books, portable multimedia players (PMPs), navigation devices, and/or ultra-mobile PCs (UMPCs). Alternatively, the display device 10 according to an embodiment may be applied as a display unit of a television, a notebook computer, a monitor, a billboard, and/or an Internet of things (IoT) device. Alternatively, the display device 10 according to the embodiment may be applied to wearable devices such as smart watches, watch phones, glass-like displays, and/or bead-mounted displays (HMDs). Alternatively, the display device 10 according to the embodiment may be applied to a dashboard of a vehicle, a center fascia of a vehicle, a center information display (CID) disposed on a dashboard of a vehicle, a room mirror display replacing side mirrors of a vehicle, and/or a display disposed on the back of a front seat as an entertainment for rear-seat passengers of a vehicle.

The display device 10 according to an embodiment may include a display panel 100 including a front portion FS, a first side portion SS1, a second side portion SS2, a third side portion SS3, a fourth side portion SS4, a first corner portion CS1, a second corner portion CS2, a third corner portion CS3, and a fourth corner portion CS4.

In an embodiment, a first direction DR1 may be a short side direction of the display panel 100, for example, a horizontal direction of the display panel 100. A second direction DR2 may be a long side direction of the display panel 100, for example, a vertical direction of the display panel 100. A third direction DR3 may be a thickness direction of the display panel 100.

In an embodiment, in addition, the display panel 100 may be a light emitting display panel including a light emitting element. For example, the display panel 100 may be an organic light emitting display panel using an organic light emitting diode including an organic light emitting layer, a micro-light emitting diode display panel using a micro-light emitting diode, a quantum dot light emitting display panel using a quantum dot light emitting diode including a quantum dot light emitting layer, and/or an inorganic light emitting display panel using an inorganic light emitting element including an inorganic semiconductor. The display panel 100 will be mainly described below as an organic light emitting display panel.

In an embodiment, the front portion FS may have a quadrilateral planar shape having short sides in the first direction DR1 and long sides in the second direction DR2, but embodiments of the present specification are not limited thereto. The front portion FS may also have other polygonal, circular, or elliptical planar shape. In FIG. 1, the front portion FS is formed to be flat, but embodiments are not limited thereto. The front portion FS may also include a curved surface.

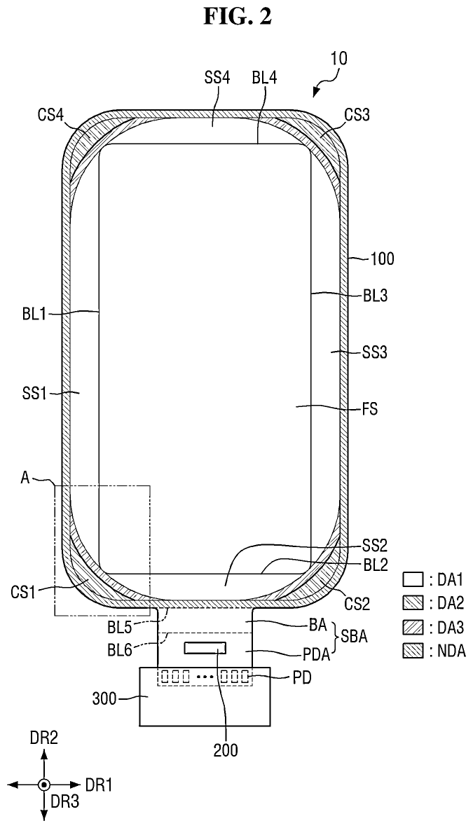

In an embodiment, the first side portion SS1 may extend from a first side portion SS1 of the front portion FS. The first side portion SS1 may be bent along a first bending line BL1 (see FIG. 2) on the first side of the front portion FS and thus may have a first curvature. The first side of the front portion FS may be a left side of the front portion FS as illustrated in FIG. 1.

In an embodiment, the second side portion SS2 may extend from a second side portion SS2 of the front portion FS. The second side portion SS2 may be bent along a second bending line BL2 (see FIG. 2) on the second side of the front portion FS and thus may have a second curvature. The second curvature may be different from the first curvature, but embodiments of the invention are not limited thereto. The second side of the front portion FS may be a lower side of the front portion FS as illustrated in FIG. 1.

In an embodiment, the third side portion SS3 may extend from a third side portion SS3 of the front portion FS. The third side portion SS3 may be bent along a third bending line BL3 (see FIG. 2) on the third side of the front portion FS and thus may have a third curvature. The third curvature may be the same as the second curvature, but embodiments of the invention are not limited thereto. The third side of the front portion FS may be a right side of the front portion FS as illustrated in FIG. 1.

In an embodiment, the fourth side portion SS4 may extend from a fourth side portion SS4 of the front portion FS. The fourth side portion SS4 may be bent along a fourth bending line BL4 (see FIG. 2) on the fourth side of the front portion FS and thus may have a fourth curvature. The fourth curvature may be the same as the first curvature, but embodiments of the invention are not limited thereto. The fourth side of the front portion FS may be an upper side of the front portion FS as illustrated in FIG. 1.

In an embodiment, the first corner portion CS1 may be disposed between the first side portion SS1 and the second side portion SS2. Specifically, the first corner portion CS1 may be in contact with a lower side of the first side portion SS1 and a left side of the second side portion SS2. The first corner portion CS1 may be a double-curvature area bent by the first curvature of the first side portion SS1 and the second curvature of the second side portion SS2. Therefore, strain may be applied to the first corner portion CS1 by a bending force of the first curvature of the first side portion SS1 and a bending force of the second curvature of the second side portion SS2.

In an embodiment, the second corner portion CS2 may be disposed between the second side portion SS2 and the third side portion SS3. Specifically, the second corner portion CS2 may be in contact with a right side of the second side portion SS2 and a lower side of the third side portion SS3. The second corner portion CS2 may be a double-curvature area bent by the second curvature of the second side portion SS2 and the third curvature of the third side portion SS3. Therefore, strain may be applied to the second corner portion CS2 by a bending force of the second curvature of the second side portion SS2 and a bending force of the third curvature of the third side portion SS3.

In an embodiment, the third corner portion CS3 may be disposed between the third side portion SS3 and the fourth side portion SS4. Specifically, the third corner portion CS3 may be in contact with an upper side of the third side portion SS3 and a right side of the fourth side portion SS4. The third corner portion CS3 may be a double-curvature area bent by the third curvature of the third side portion SS3 and the fourth curvature of the fourth side portion SS4. Therefore, strain may be applied to the third corner portion CS3 by a bending force of the third curvature of the third side portion SS3 and a bending force of the fourth curvature of the fourth side portion SS4.

In an embodiment, the fourth corner portion CS4 may be disposed between the first side portion SS1 and the fourth side portion SS4. Specifically, the fourth corner portion CS4 may be in contact with an upper side of the first side portion SS1 and a left side of the fourth side portion SS4. The fourth corner portion CS4 may be a double-curvature area bent by the first curvature of the first side portion SS1 and the fourth curvature of the fourth side portion SS4. Therefore, strain may be applied to the fourth corner portion CS4 by a bending force of the first curvature of the first side portion SS1 and a bending force of the fourth curvature of the fourth side portion SS4.

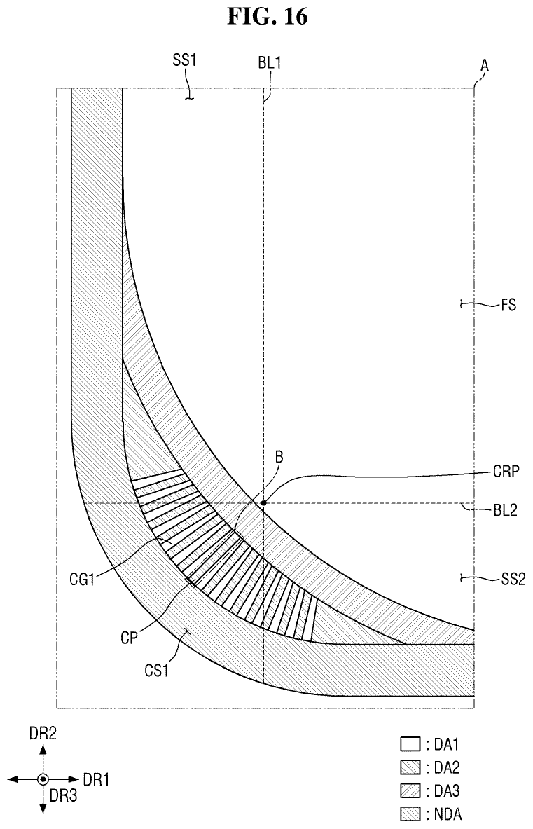

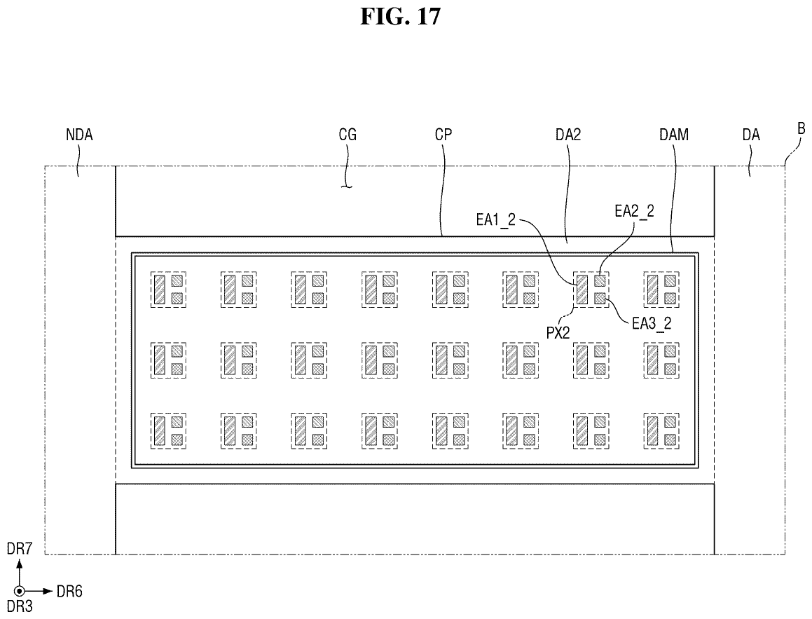

Each of the first corner portion CS1, the second corner portion CS2, the third corner portion CS3, and the fourth corner portion CS4 may include cutout patterns separated by cutout portions as illustrated in FIGS. 16 and 17 in order to reduce strain due to the double curvature. The cutout patterns will be described later with reference to FIGS. 16 and 17.

FIG. 2 is a development drawing of the display device 10 according to an embodiment.

In an embodiment and referring to FIG. 2, the display panel 100 may further include a bending portion BA and a pad portion PDA. The display panel 100 may include first through third display areas DA1 through DA3, respectively, a non-display area NDA, the bending portion BA, and the pad portion PDA.

In an embodiment, the first through third display areas DA1 through DA3, respectively, refer to areas that include pixels or emission areas to display an image. The non-display area NDA refers to an area that does not display an image because it does not include pixels or emission areas. Signal wirings and/or a scan driver for driving pixels and/or emission areas may be disposed in the non-display area NDA.

In an embodiment, the first display area DA1 may be a main display area of the display panel 100 and may be disposed in the front portion FS, the first side portion SS1, the second side portion SS2, the third side portion SS3, and the fourth side portion SS4. Each corner of the first display area DA1 may be rounded with a predetermined curvature.

In an embodiment, the second display area DA2 may be a first auxiliary display area assisting the first display area DA1 which is the main display area. The resolution of the second display area DA2 may be different from the resolution of the first display area DA1. For example, since the second display area DA2 serves to assist the first display area DA1, the resolution of the second display area DA2 may be lower than the resolution of the first display area DA1. For example, the number of pixels per unit area in the second display area DA2 may be less than the number of pixels per unit area in the first display area DA1. Alternatively, the number of pixels per inch (PPI) in the second display area DA2 may be less than the number of pixels per inch in the first display area DA1. However, embodiments of the invention are not limited thereto, and the resolution of the second display area DA2 may also be substantially the same as the resolution of the first display area DA1.

In an embodiment, the second display area DA2 may be disposed outside any one of the corners of the first display area DA1. The second display area DA2 may be disposed in any one of the corner portions CS1 through CS4.

In an embodiment, for example, the second display area DA2 disposed outside a corner where a lower side and a left side of the first display area DA meet may be disposed in the first corner portion CS1. The second display area DA2 disposed outside a corner where the lower side and a right side of the first display area DA1 meet may be disposed in the second corner portion CS2. The second display area DA2 disposed outside a corner where an upper side and the right side of the first display area DA1 meet may be disposed in the third corner portion CS3. The second display area DA2 disposed outside a corner where the upper side and the left side of the first display area DA1 meet may be disposed in the fourth corner portion CS4.

In an embodiment, the third display area DA3 may be a second auxiliary display area assisting the first display area DA1 which is the main display area. The resolution of the third display area DA3 may be different from the resolution of the first display area DA1. For example, since the third display area DA3 serves to assist the first display area DA1, the resolution of the third display area DA3 may be lower than the resolution of the first display area DA1. That is, the number of pixels per unit area in the third display area DA3 may be less than the number of pixels per unit area in the first display area DA1. Alternatively, the number of pixels per inch in the third display area DA3 may be less than the number of pixels per inch in the first display area DA1. However, embodiments of the invention are not limited thereto, and the resolution of the third display area DA3 may also be substantially the same as the resolution of the first display area DA1.

In an embodiment, the third display area DA3 may be disposed between the first display area DA1 and the second display area DA2. The third display area DA3 may be disposed in any one of the corner portions CS1 through CS4.

In an embodiment, for example, the third display area DA3 disposed outside the corner where the lower side and the left side of the first display area DA1 meet may be disposed in the first corner portion CS1. The third display area DA3 disposed outside the corner where the upper side and the left side of the first display area DA1 meet may be disposed in the fourth corner portion CS4. The third display area DA3 disposed outside the corner where the lower side and the right side of the first display area DA1 meet may be disposed in the second corner portion CS2. The third display area DA3 disposed outside the corner where the upper side and the right side of the first display area DA1 meet may be disposed in the third corner area CS3.

In an embodiment, the non-display area NDA may be disposed in the first side portion SS1, the second side portion SS2, the third side portion SS3, the fourth side portion SS4, the first corner portion CS1, the second corner portion CS2, the third corner portion CS3, and the fourth corner portion CS4. The non-display area NDA may be disposed in the side portions SS1 through SS4 outside the first display area DA1. For example, the non-display area NDA may be disposed at a left edge of the first side portion SS1, a lower edge of the second side portion SS2, a right edge of the third side portion SS3, and an upper edge of the fourth side portion SS4.

In an embodiment, the non-display area NDA may be disposed in the corner portions CS1 through CS4 outside the second display area DA2. For example, the non-display area NDA may be disposed at an edge of a corner where a lower side and a left side of the first corner portion CS1 meet, an edge of a corner where a lower side and a right side of the second corner portion CS2 meet, an edge of a corner where an upper side and a right side of the third corner portion CS3 meet, and an edge of a corner where an upper side and a left side of the fourth corner portion CS4 meet.

In an embodiment, the bending portion BA may extend from a lower side of the second side portion SS2. The bending portion BA may be disposed between the second side portion SS2 and the pad portion PDA. A length of the bending portion BA in the first direction DR1 may be shorter than a length of the second side portion SS2 in the first direction DR1. The bending portion BA may be bent along a fifth bending line BL5 on the lower side of the second side portion SS2.

In an embodiment, the pad portion PDA may extend from a lower side of the bending portion BA. A length of the pad portion PDA in the first direction DR1 may be longer than the length of the bending portion BA in the first direction DR1, but embodiments of the invention are not limited thereto. The length of the pad portion PDA in the first direction DR1 may also be substantially the same as the length of the bending portion BA in the first direction DR1. The pad portion PDA may be bent along a sixth bending line BL6 on the lower side of the bending portion BA. The pad portion PDA may be disposed on a lower surface of the front portion FS.

In an embodiment, a display driving circuit 200 and pads PD may be disposed on the pad portion PDA. The display driving circuit 200 may be formed as an integrated circuit. The display driving circuit 200 may be attached onto the pad portion PDA using a chip on plastic (COP) method or an ultrasonic bonding method. Alternatively, the display driving circuit 200 may be disposed on a display circuit board 300 disposed on the pads PD of the pad portion PDA.

In an embodiment, the display circuit board 300 may be attached onto the pads PD of the pad portion PDA using an anisotropic conductive film. Accordingly, the pads PD of the pad portion PDA may be electrically connected to the display circuit board 300.

In an embodiment and as illustrated in FIG. 2, the display areas DA1 through DA3 may be disposed in the front portion FS, the first side portion SS1, the second side portion SS2, the third side portion SS3, the fourth side portion SS4, the first corner portion CS1, the second corner portion CS2, the third corner portion CS3, and the fourth corner portion CS4 of the display panel 100. Therefore, an image may be displayed not only on the front portion FS, the first side portion SS1, the second side portion SS2, the third side portion SS3, and the fourth side portion SS4 of the display panel 100, but also on the first corner portion CS1, the second corner portion CS2, the third corner portion CS3, and the fourth corner portion CS4.

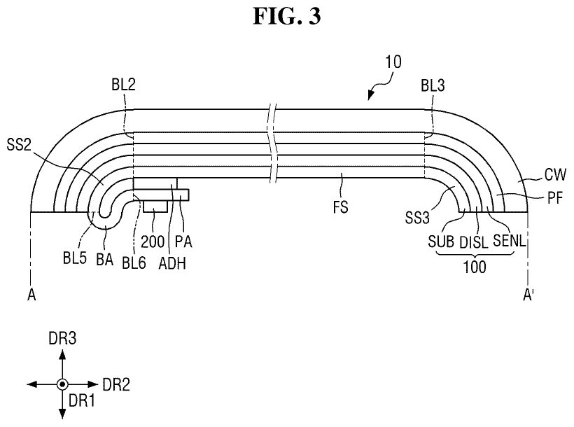

FIG. 3 is a cross-sectional view of the display device 10 according to an embodiment. FIG. 3 illustrates an example of the display device 10 cut along line A-A′ of FIG. 1.

In an embodiment and referring to FIG. 3, the display device 10 may further include a cover window CW and a polarizing film PF in addition to the display panel 100. The display panel 100 may include a substrate SUB, a display layer DISL, and a touch electrode layer SENL. The polarizing film PF may be disposed on the display panel 100, and the cover window CW may be disposed on the polarizing film PF.

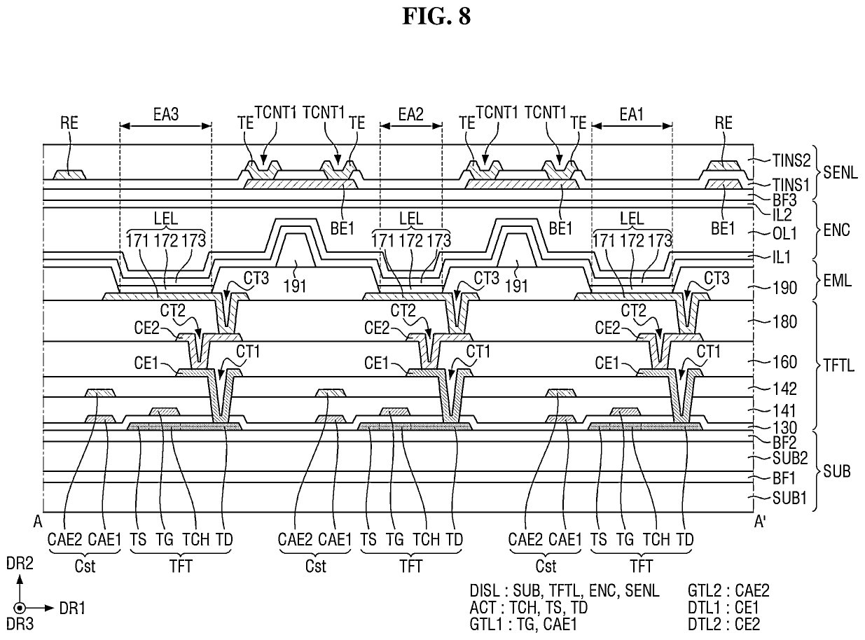

In an embodiment, the display layer DISL may be disposed on the substrate SUB. The display layer DISL may include the display areas DA1 through DA3 (see FIG. 2) and the non-display area NDA. The display layer DISL may include a thin-film transistor layer TFTL (see FIG. 8), a light emitting element layer EML (see FIG. 8) in which light emitting elements emitting light are disposed, and an encapsulation layer ENC (see FIG. 8) for encapsulating the light emitting element layer EML.

In an embodiment, the touch electrode layer SENL, the polarizing film PF, and the cover window CW may be disposed on the second side portion SS2 and the third side portion SS3. The touch electrode layer SENL, the polarizing film PF, and the cover window CW may also be disposed on the first side portion SS1 and the fourth side portion SS4.

In an embodiment, the bending portion BA may be bent at the fifth bending line BL5 to lie on a lower surface of the second side portion SS2. The pad portion PDA may be bent at the sixth bending line BL6 to lie on the lower surface of the front portion FS. The pad portion PDA may be attached to the lower surface of the front portion FS by an adhesive member ADH. The adhesive member ADH may be a pressure sensitive adhesive.

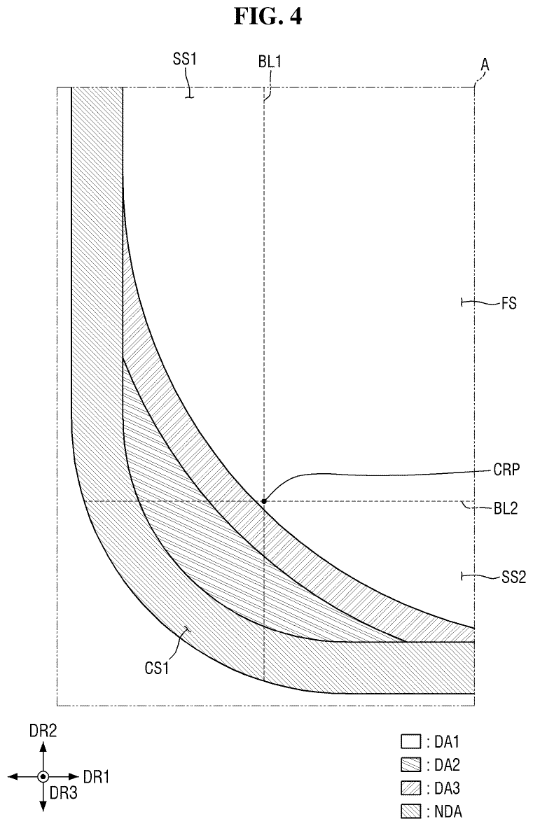

FIG. 4 is an enlarged layout view illustrating, in detail, the first through third display areas DA1 through DA3 and the non-display area NDA disposed in the first corner portion CS1 of the display panel 100 according to an embodiment. FIG. 4 is an enlarged view of area A of FIG. 2.

In an embodiment and referring to FIG. 4, an intersection point CRP of the first bending line BL1 and the second bending line BL2 may be disposed in the first display area DA1. In this case, the first display area DA1 may be disposed in the front portion FS, the first side portion SS1, the second side portion SS2, and the first corner portion CS1. In this case, the second display area DA2 and the third display area DA3 may be disposed in the first corner portion CS1. The non-display area NDA may be disposed in the first side portion SS1, the second side portion SS2, and the first corner portion CS1.

In an embodiment, the position of the intersection point CRP of the first bending line BL1 and the second bending line BL2 is not limited to that illustrated in FIG. 4, and the intersection point CRP may also be disposed in the second display area DA2 and/or the third display area DA3.

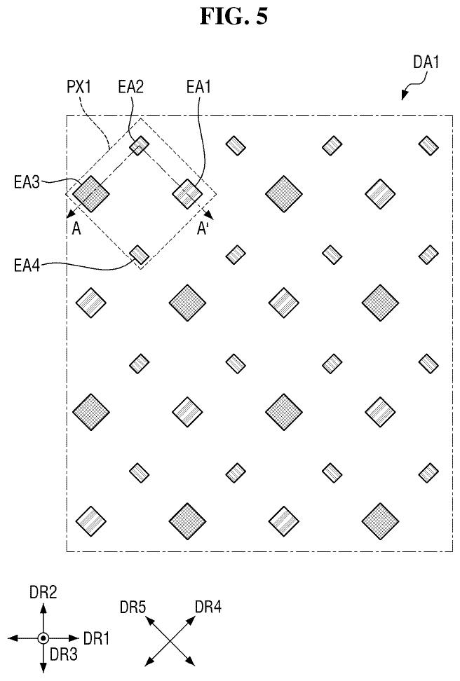

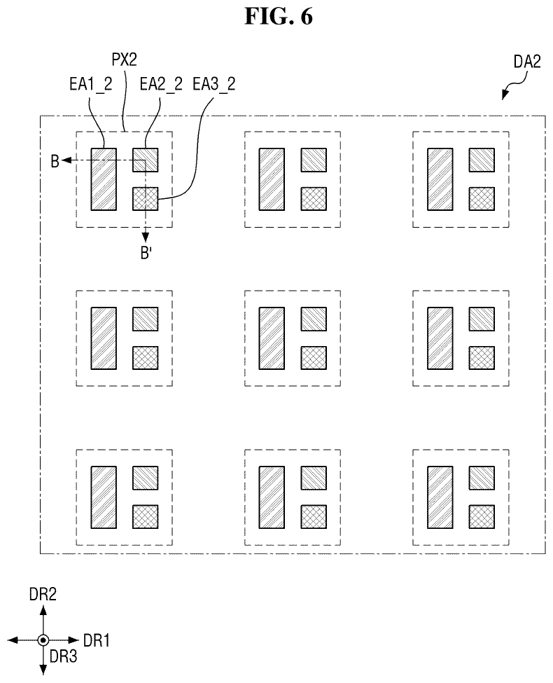

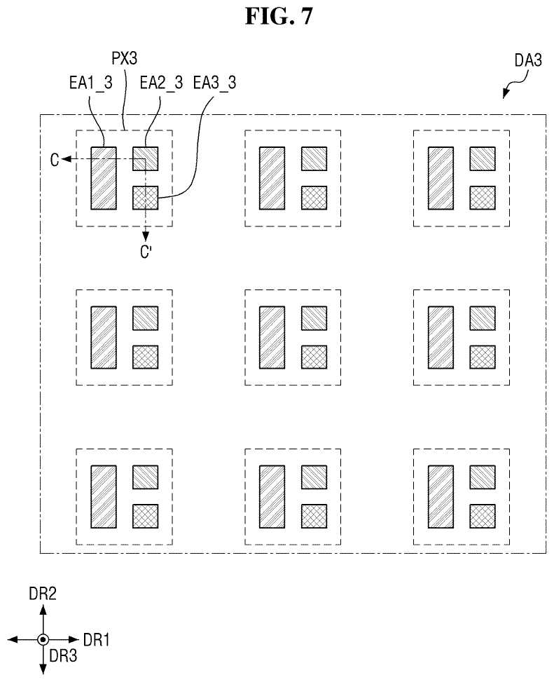

In an embodiment, the first display area DA1 may include first pixels PX1 (see FIG. 5) displaying an image. The second display area DA2 may be disposed outside the third display area DA3. The second display area DA2 may include second pixels PX2 (see FIG. 6) displaying an image. The third display area DA3 may be disposed between the first display area DA1 and the second display area DA2. The third display area DA3 may include third pixels PX3 (see FIG. 7) displaying an image.

In an embodiment, when a non-display area is disposed instead of the third display area DA3, a user may recognize the non-display area between the first display area DA1 and the second display area DA2. That is, the user may recognize a gap between an image displayed by the first display area DA1 and an image displayed by the second display area DA2. When the third display area DA3 including the third pixels PX3 (see FIG. 7) is disposed between the first display area DA1 and the second display area DA2, it is possible to prevent the gap between the image displayed by the first display area DA1 and the image displayed by the second display area DA2 from being recognized by the user.

In an embodiment, a scan driver for transmitting scan signals to the first pixels PX1 (see FIG. 5) of the first display area DA1, the second pixels PX2 (see FIG. 6) of the second display area DA2, and the third pixels PX3 (see FIG. 7) of the third display area DA3 may be disposed in the third display area DA3 and the non-display area NDA. Alternatively, the scan driver may be disposed only in the non-display area NDA.

In an embodiment, the display areas DA1 through DA3 and the non-display area NDA disposed in the second corner portion CS2, the third corner portion CS3, and the fourth corner portion CS4 illustrated in FIG. 2 may be similar to those described with reference to FIG. 4. Therefore, a description of the second corner portion CS2, the third corner portion CS3, and the fourth corner portion CS4 will be omitted.

FIG. 5 is a detailed plan view of an example of the first display area DA1 of FIG. 4, according to an embodiment.

Referring to FIG. 5, the first display area DA1 may include the first pixels PX1. In an embodiment, each of the first pixels PX1 may include first through fourth emission areas EA1 through EA4, respectively.

The first emission area EA1 may have a rectangular or rhombic planar shape having sides in a fourth direction DR4 and sides in a fifth direction DR5. The second emission area EA2 may have a rectangular planar shape having long sides in the fourth direction DR4 and short sides in the fifth direction DR5. The third emission area EA3 may have a rectangular or rhombic planar shape having sides in the fourth direction DR4 and sides in the fifth direction DR5. The fourth emission area EA4 may have a rectangular planar shape having short sides in the fourth direction DR4 and long sides in the fifth direction DR5. The fourth direction DR4 and the fifth direction DR5 may be orthogonal to each other. The fourth direction DR4 may directed in a diagonal direction inclined by 45 degrees with respect to the first direction DR1.

In an embodiment, the area of the third emission area EA3 may be the largest, and the area of the second emission area EA2 and the area of the fourth emission area EA4 may be the smallest. The area of the second emission area EA2 and the area of the fourth emission area EA4 may be substantially the same.

In an embodiment, the first emission area EA1 may emit light of a first color, the second emission area EA2 and the fourth emission area EA4 may emit light of a second color, and/or the third emission area EA3 may emit light of a third color. The light of the first color may indicate light of a red wavelength band, the light of the second color may indicate light of a green wavelength band, and/or the light of the third color may indicate light of a blue wavelength band. Alternatively, the first through fourth emission areas EA1 through EA4, respectively, may emit light of different colors.

FIG. 6 is a plan view of an example of the second display area DA2 of FIG. 4, according to an embodiment.

Referring to FIG. 6, the second display area DA2 may include the second pixels PX2. In an embodiment, each of the second pixels PX2 may include first through third emission areas EA1_2, EA2_2, and EA3_2, respectively.

In an embodiment, the first emission area EA1_2 may have a rectangular planar shape having short sides in the first direction DR1 and long sides in the second direction DR2. The second emission area EA2_2 may have a rectangular or square planar shape having sides in the first direction DR1 and sides in the second direction DR2. The third emission area EA3_2 may have a rectangular or square planar shape having sides in the first direction DR1 and sides in the second direction DR2. The first direction DR1 and the second direction DR2 may be orthogonal to each other.

In an embodiment, the area of the first emission area EA1_2 may be the largest, and the area of the second emission area EA2_2 and the area of the third emission area EA3_2 may be the smallest. The area of the second emission area EA2_2 and the area of the third emission area EA3_2 may be substantially the same.

In an embodiment, the first emission area EA1_2 may emit light of a first color, the second emission area EA2_2 may emit light of a second color, and/or the third emission area EA3_2 may emit light of a third color. The light of the first color may indicate light of a red wavelength band, the light of the second color may indicate light of a green wavelength band, and/or the light of the third color may indicate light of a blue wavelength band.

FIG. 7 is a plan view of an example of the third display area DA3 of FIG. 4, according to an embodiment.

Referring to FIG. 7, the third display area DA3 may include the third pixels PX3. In an embodiment, each of the third pixels PX3 may include first through third emission areas EA1_3, EA2_3, and EA3_3, respectively.

In an embodiment, the first emission area EA1_3 may have a rectangular planar shape having short sides in the first direction DR1 and long sides in the second direction DR2. The second emission area EA2_3 may have a rectangular or square planar shape having sides in the first direction DR1 and sides in the second direction DR2. The third emission area EA3_3 may have a rectangular or square planar shape having sides in the first direction DR1 and sides in the second direction DR2.

In an embodiment, the area of the first emission area EA1_3 may be the largest, and the area of the second emission area EA2_3 and the area of the third emission area EA3_3 may be the smallest. The area of the second emission area EA2_3 and the area of the third emission area EA3_3 may be substantially the same.

In an embodiment, the first emission area EA1_3 may emit light of a first color, the second emission area EA2_3 may emit light of a second color, and/or the third emission area EA3_3 may emit light of a third color. The light of the first color may indicate light of a red wavelength band, the light of the second color may indicate light of a green wavelength band, and/or the light of the third color may indicate light of a blue wavelength band.

In an embodiment, the first display area DA1 may be a main display area displaying a main image, and the second display area DA2 and the third display area DA3 may be sub-display areas displaying sub-images. Therefore, the density of the first pixels PX1 in the first display area DA1 may be higher than the density of the second pixels PX2 in the second display area DA2. The density of the first pixels PX1 in the first display area DA1 may be higher than the density of the third pixels PX3 in the third display area DA3. The density of the second pixels PX2 in the second display area DA2 may be substantially the same as the density of the third pixels PX3 in the third display area DA3.

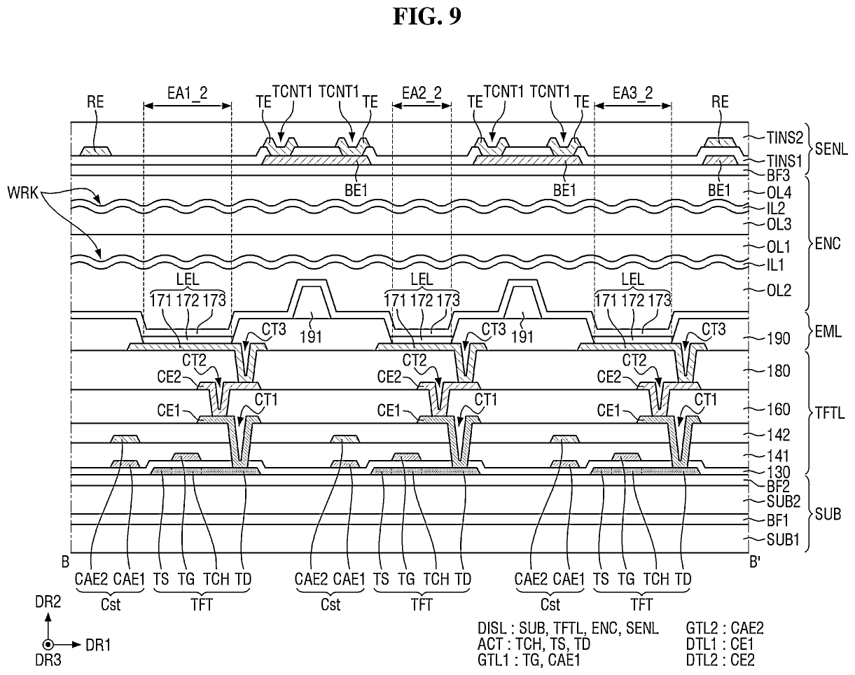

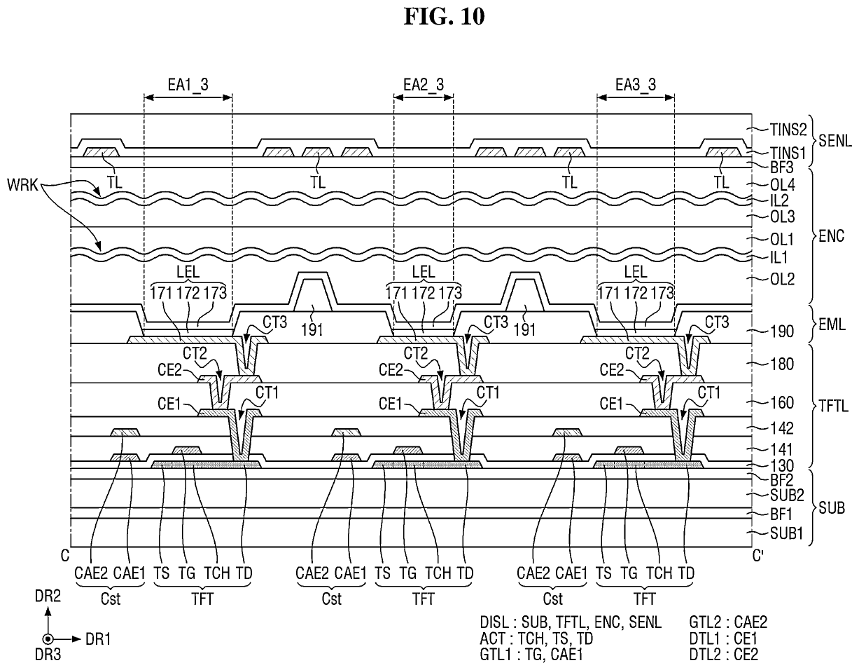

FIG. 8 is a cross-sectional view of an example of the display panel 100 taken along line A-A′ of FIG. 5, according to an embodiment. FIG. 9 is a cross-sectional view of an example of the display panel 100 taken along line B-B′ of FIG. 6, according to an embodiment. FIG. 10 is a cross-sectional view of an example of the display panel 100 taken along line C-C′ of FIG. 7, according to an embodiment. FIG. 8 illustrates a cross section of the first emission area EA1, the second emission area EA2, and the third emission area EA3 of a first pixel PX1. FIG. 9 illustrates a cross section of the first emission area EA1_2, the second emission area EA2_2, and the third emission area EA3_2 of a second pixel PX2. FIG. 10 illustrates a cross section of the first emission area EA1_3, the second emission area EA2_3, and the third emission area EA3_3 of a third pixel PX3.

In an embodiment and referring to FIGS. 8 through 10, the substrate SUB may include a first substrate SUB1, a first buffer layer BF1, a second substrate SUB2, and a second buffer layer BF2.

In an embodiment, the first substrate SUB1 may be made of an organic layer such as acryl resin, epoxy resin, phenolic resin, polyamide resin, and/or polyimide resin.

In an embodiment, the first buffer layer BF1 may be disposed on the first substrate SUB1. The first buffer layer BF1 may be made of a silicon nitride layer, a silicon oxynitride layer, a silicon oxide layer, a titanium oxide layer, and/or an aluminum oxide layer. Alternatively, the first buffer layer BF1 may have a structure in which any two of a silicon nitride layer, a silicon oxynitride layer, a silicon oxide layer, a titanium oxide layer, and/or an aluminum oxide layer are alternately stacked.

In an embodiment, the second substrate SUB2 may be disposed on the first buffer layer BF1. The second substrate SUB2 may include substantially the same material as the first substrate SUB1. The second substrate SUB2 may be made of an organic layer such as acryl resin, epoxy resin, phenolic resin, polyamide resin, and/or polyimide resin.

In an embodiment, the second buffer layer BF2 may be disposed on the second substrate SUB2. The second buffer layer BF2 may be made of a silicon nitride layer, a silicon oxynitride layer, a silicon oxide layer, a titanium oxide layer, and/or an aluminum oxide layer. Alternatively, the second buffer layer BF2 may have a structure in which any two of a silicon nitride layer, a silicon oxynitride layer, a silicon oxide layer, a titanium oxide layer, and/or an aluminum oxide layer are alternately stacked. The first buffer layer BF1, the second buffer layer BF2, a first encapsulating inorganic layer IL1, and/or a second encapsulating inorganic layer IL2 may contact each other at edges of the substrate SUB. Therefore, it is possible to prevent oxygen and/or moisture from penetrating into light emitting elements LEL of the light emitting element layer EML.

In an embodiment, the thin-film transistor layer TFTL may be disposed on the substrate SUB. The thin-film transistor layer TFTL may be a layer in which thin-film transistors TFT and capacitors Cst are formed.

In an embodiment, the thin-film transistor layer TFTL includes an active layer ACT and a plurality of metal layers. The metal layers may include a first gate metal layer GTL1, a second gate metal layer GTL2, a first data metal layer DTL1, and a second data metal layer DTL2. In addition, the thin-film transistor layer TFTL may include a plurality of insulating layers. The insulating layers may include a gate insulating layer 130, a first interlayer insulating layer 141, a second interlayer insulating layer 142, a first planarization layer 160, and/or a second planarization layer 180.

In an embodiment, the active layer ACT may be disposed on the substrate SUB. The active layer ACT may include a silicon semiconductor such as polycrystalline silicon, monocrystalline silicon, low-temperature polycrystalline silicon and/or amorphous silicon and/or may include an oxide semiconductor.

In an embodiment, the active layer ACT may include a channel layer TCH, a first electrode TS and a second electrode TD of each thin-film transistor TFT. The first electrode TS may be any one of a source electrode and a drain electrode of each thin-film transistor TFT, and/or the second electrode TD may be the other one. The channel layer TCH of each thin-film transistor TFT may be a region overlapping a gate electrode TG of the thin-film transistor TFT in the third direction DR3 which is the thickness direction of the substrate SUB. The first electrode TS of each thin-film transistor TFT may be disposed on one side of the channel layer TCH, and the second electrode TD may be disposed on the other side of the channel layer TCH. The first electrode TS and the second electrode TD of each thin-film transistor TFT may be regions not overlapping the gate electrode TG in the third direction DR3. The first electrode TS and the second electrode TD of each thin-film transistor TFT may be regions formed to have conductivity by doping a silicon semiconductor and/or an oxide semiconductor with ions or impurities.

In an embodiment, the gate insulating layer 130 may be disposed on the active layer ACT. The gate insulating layer 130 may be made of an inorganic layer, for example, a silicon nitride layer, a silicon oxynitride layer, a silicon oxide layer, a titanium oxide layer, and/or an aluminum oxide layer.

In an embodiment, the first gate metal layer GTL1 may be disposed on the gate insulating layer 130. The first gate metal layer GTL1 may include the gate electrode TG of each thin-film transistor TFT and a first capacitor electrode CAE1 of each capacitor Cst. The first gate metal layer GTL1 may be a single layer or a multilayer made of any one or more of molybdenum (Mo), aluminum (Al), chromium (Cr), gold (Au), titanium (Ti), nickel (Ni), neodymium (Nd), copper (Cu), and/or alloys thereof.

In an embodiment, the first interlayer insulating layer 141 may be disposed on the first gate metal layer GTL1. The first interlayer insulating layer 141 may be made of an inorganic layer, for example, a silicon nitride layer, a silicon oxynitride layer, a silicon oxide layer, a titanium oxide layer, and/or an aluminum oxide layer.

In an embodiment, the second gate metal layer GTL2 may be disposed on the first interlayer insulating layer 141. The second gate metal layer GTL2 may include a second capacitor electrode CAE2 of each capacitor Cst. The second capacitor electrode CAE2 may overlap the first capacitor electrode CAE1 in the third direction DR3. The second gate metal layer GTL2 may be a single layer or a multilayer made of any one or more of molybdenum (Mo), aluminum (Al), chromium (Cr), gold (Au), titanium (Ti), nickel (Ni), neodymium (Nd), copper (Cu), and/or alloys thereof.

In an embodiment, the second interlayer insulating layer 142 may be disposed on the second gate metal layer GTL2. The second interlayer insulating layer 142 may be made of an inorganic layer, for example, a silicon nitride layer, a silicon oxynitride layer, a silicon oxide layer, a titanium oxide layer, and/or an aluminum oxide layer.

In an embodiment, the first data metal layer DTL1 may include first connection electrodes CE1 and may be disposed on the second interlayer insulating layer 142. Each of the first connection electrodes CE1 may be connected to the second electrode TD of a thin-film transistor TFT through a first contact hole CT1 penetrating the gate insulating layer 130, the first interlayer insulating layer 141, and the second interlayer insulating layer 142. The first data metal layer DTL1 may be a single layer or a multilayer made of any one or more of molybdenum (Mo), aluminum (Al), chromium (Cr), gold (Au), titanium (Ti), nickel (Ni), neodymium (Nd), copper (Cu), and/or alloys thereof.

In an embodiment, the first planarization layer 160 may be formed on the first data metal layer DTL1 to flatten steps due to the active layer ACT, the first gate metal layer GTL1, the second gate metal layer GTL2, and the first data metal layer DTL1. The first planarization layer 160 may be made of an organic layer such as acryl resin, epoxy resin, phenolic resin, polyamide resin, and/or polyimide resin.

In an embodiment, the second data metal layer DTL2 may be formed on the first planarization layer 160. The second data metal layer DTL2 may include second connection electrodes CE2. Each of the second connection electrodes CE2 may be connected to a first connection electrode CE1 through a second contact hole CT2 penetrating the first planarization layer 160. The second data metal layer DTL2 may be a single layer or a multilayer made of any one or more of molybdenum (Mo), aluminum (Al), chromium (Cr), gold (Au), titanium (Ti), nickel (Ni), neodymium (Nd), copper (Cu), and/or alloys thereof.

In an embodiment, the second planarization layer 180 may be formed on the second data metal layer DTL2 to flatten steps. The second planarization layer 180 may be made of an organic layer such as acryl resin, epoxy resin, phenolic resin, polyamide resin, and/or polyimide resin.

In an embodiment, the light emitting element layer EML may be disposed on the second planarization layer 180. The light emitting element layer EML may include a plurality of light emitting elements LEL and/or a bank 190. Each of the light emitting elements LEL may include a first electrode 171, a light emitting layer 172, and/or a second electrode 173. Each of the light emitting elements LEL refers to an element in which the first electrode 171, the light emitting layer 172, and/or the second electrode 173 are sequentially stacked so that holes from the first electrode 171 and electrons from the second electrode 173 recombine in the light emitting layer 172 to emit light. The first electrode 171 may be an anode, and the second electrode 173 may be a cathode.

In an embodiment, the first electrode 171 may be disposed on the second planarization layer 180. The first electrode 171 may be connected to each of the second connection electrodes CE2 through a third contact hole CT3 penetrating the second planarization layer 180. The first electrode 171 may be made of a metal material having high reflectivity, such as a stacked structure (Ti/Al/Ti) of aluminum and titanium, a stacked structure (ITO/AI/ITO) of aluminum and indium tin oxide, an APC alloy, and/or a stacked structure (ITO/APC/ITO) of an APC alloy and indium tin oxide. The APC alloy is an alloy of silver (Ag), palladium (Pd), and copper (Cu).

In an embodiment, in the first display area DA1, the bank 190 may define the first through fourth emission areas EA1 through EA4, respectively, of each of the first pixels PX1 in which a plurality of light emitting elements LEL are disposed. In addition, in the second display area DA2, the bank 190 may define the first through third emission areas EA1_2, EA2_2 and EA3_2, respectively, of each of the second pixels PX2 in which a plurality of light emitting elements LEL are disposed. In addition, in the third display area DA3, the bank 190 may define the first through third emission areas EA1_3, EA2_3 and EA3_3, respectively, of each of the third pixels PX3 in which a plurality of light emitting elements LEL are disposed. That is, the bank 190 may be an emission area defining layer that defines the first through fourth emission areas EA1 through EA4, respectively, of each of the first pixels PX1, the first through third emission areas EA1_2, EA2_2 and EA3_2, respectively, of each of the second pixels PX2, and the first through third emission areas EA1_3, EA2_3 and EA3_3, respectively, of each of the third pixels PX3.

In an embodiment, the bank 190 may be formed to cover edges of the first electrode 171 of each of the light emitting elements LEL. The bank 190 may be made of an organic layer such as acryl resin, epoxy resin, phenolic resin, polyamide resin, and/or polyimide resin.

In an embodiment, the light emitting layer 172 may be disposed on the first electrode 171. The light emitting layer 172 may include an organic material to emit light of a predetermined color. For example, the light emitting layer 172 may include a hole transporting layer, an organic material layer, and/or an electron transporting layer.

In an embodiment, the second electrode 173 may be disposed on the light emitting layer 172 and/or the bank 190. The second electrode 173 may be formed to cover an upper surface of the light emitting layer 172 and/or an upper surface of the bank 190. The second electrode 173 may be commonly disposed over the first display area DA1, the second display area DA2, and/or the third display area DA3 as a whole.

In an embodiment, in a top emission structure, the second electrode 173 may be made of a transparent conductive material (TCO) capable of transmitting light, such as indium tin oxide (ITO) and/or indium zinc oxide (IZO), and/or a semi-transmissive conductive material such as magnesium (Mg), silver (Ag) and/or an alloy of Mg and Ag. When the second electrode 173 is made of a semi-transmissive conductive material, the light output efficiency of each of the light emitting elements LEL may be increased by a microcavity.

In an embodiment, a capping layer made of an inorganic material may be additionally disposed on the second electrode 173.

In an embodiment, the encapsulation layer ENC may be formed on the light emitting element layer EML. The encapsulation layer ENC may include at least one inorganic layer to prevent penetration of oxygen and/or moisture into the light emitting element layer EML. In addition, the encapsulation layer ENC may include at least one organic layer to protect the light emitting element layer EML from foreign substances such as dust. In addition, the encapsulation layer ENC may include a stacked structure of at least one organic layer and/or at least one inorganic layer to form a wrinkle portion in order to reduce the strain applied to the display panel 100.

In an embodiment, the encapsulation layer ENC may include a plurality of encapsulating inorganic layers IL1 and IL2 and a plurality of encapsulating organic layers OL1 through OL4. The encapsulating inorganic layers IL1 and IL2 may include the first encapsulating inorganic layer IL1 and the second encapsulating inorganic layer IL2. The encapsulating organic layers OL1 through OL3 may include a first encapsulating organic layer OL1, a second encapsulating organic layer OL2, a third encapsulating organic layer OL3, and a fourth encapsulating organic layer OL4.

In an embodiment, each of the first encapsulating inorganic layer IL1 and the second encapsulating inorganic layer IL2 may be a multilayer in which one or more inorganic layers selected from a silicon nitride layer, a silicon oxynitride layer, a silicon oxide layer, a titanium oxide layer, and/or an aluminum oxide layer may be alternately stacked. The first encapsulating inorganic layer IL1 and/or the second encapsulating inorganic layer IL2 may not only prevent penetration of oxygen and/or moisture into the light emitting element layer EML, but also form a wrinkle portion in order to reduce the strain applied to the display panel 100.

In an embodiment, the first encapsulating organic layer OL1 may be a monomer. The first encapsulating organic layer OL1 may protect the light emitting element layer EML from foreign substances such as dust.

In an embodiment, the second encapsulating organic layer OL2 and the third encapsulating organic layer OL3 may be made of hexamethyldisiloxane (HMDSO). The second encapsulating organic layer OL2 and the third encapsulating organic layer OL3 may form a wrinkle portion in order to reduce the strain applied to the display panel 100.

In an embodiment, the first encapsulating inorganic layer IL1, the first encapsulating organic layer OL1, and the second encapsulating inorganic layer IL2 may be disposed in the first display area DA1 in the front portion FS and the side portions SS1 through SS4 and may be disposed in the second display area DA2 and the third display area DA3 in the side portions SS1 through SS4 and the corner portions CS1 through CS4. The second encapsulating organic layer OL2 and the third encapsulating organic layer OL3 may be disposed in the second display area DA2 in the side portions SS1 through SS4 and the corner portions CS1 through CS4.

In an embodiment, that is, the first encapsulating inorganic layer IL1, the first encapsulating organic layer OL1, and the second encapsulating inorganic layer IL2 may be sequentially disposed on the second electrode 173 of the light emitting element layer EML in the first display area DA1. On the other hand, the second encapsulating organic layer OL2, the first encapsulating inorganic layer IL1, the first encapsulating organic layer OL1, the second encapsulating inorganic layer IL2, and the third encapsulating organic layer OL3 may be sequentially disposed on the second electrode 173 of the light emitting element layer EML in the second display area DA2 and the third display area DA3.

In an embodiment, a modulus of the second encapsulating organic layer OL2 may be smaller than a modulus of the first encapsulating inorganic layer IL1. Here, the modulus of the second encapsulating organic layer OL2 may be smaller than the modulus of the first encapsulating inorganic layer IL1 by at least about 300 MPa.

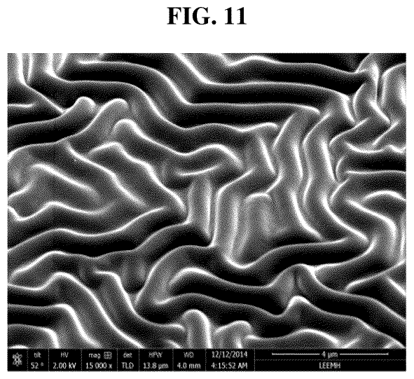

In an embodiment, when a material layer having a high modulus is formed on a material layer having a low modulus, a wrinkle portion WRK may be formed between the two layers due to a difference between the moduli of the two layers. That is, when the second encapsulating organic layer OL2 and the first encapsulating inorganic layer IL1 having different moduli are formed without a special process, the wrinkle portion WRK may be naturally formed at a boundary between the second encapsulating organic layer OL2 and the first encapsulating inorganic layer IL1 as illustrated in FIGS. 9 and 10 due to thin-film stress. The wrinkle portion WRK may not be formed to have regular intervals or shapes, but may be irregularly formed as illustrated in FIG. 11.

In an embodiment, a modulus of the third encapsulating organic layer OL3 may be smaller than a modulus of the second encapsulating inorganic layer IL2. Here, the modulus of the third encapsulating organic layer OL3 may be smaller than the modulus of the second encapsulating inorganic layer IL2 by at least about 300 MPa. When the third encapsulating organic layer OL3 and the second encapsulating inorganic layer IL2 having different moduli are formed without a special process, the wrinkle portion WRK may be naturally formed at a boundary between the third encapsulating organic layer OL3 and the second encapsulating inorganic layer IL2 as illustrated in FIGS. 9 and 10 due to thin-film stress. The wrinkle portion WRK may not be formed to have regular intervals or shapes, but may be irregularly formed as illustrated in FIG. 11. FIG. 11 shows an image of the third encapsulating organic layer OL3 and the second encapsulating inorganic layer IL2 captured using a focused ion beam (FIB), according to an embodiment.

In an embodiment, the corner portions CS1 through CS4 in which the second display area DA2 and the third display area DA3 are disposed may be double-curvature areas to which high strain is applied. The encapsulation layer ENC having the wrinkle portion WRK is advantageous in stretch and compression compared with the encapsulation layer ENC not having the wrinkle portion WRK. Therefore, the formation of the encapsulation layer ENC having the wrinkle portion WRK in the second display area DA2 and the third display area DA3 may reduce the strain of the encapsulation layer ENC in the corner portions CS1 through CS4 which are double-curvature areas.

In an embodiment, the fourth encapsulating organic layer OL4 may be disposed on the second encapsulating inorganic layer IL2. The fourth encapsulating organic layer OL4 may be a planarization layer for flattening steps due to the wrinkle portion WRK before the touch electrode layer SENL is formed. The fourth encapsulating organic layer OL4 may be a monomer. Alternatively, the fourth encapsulating organic layer OL4 may be made of an organic layer such as acryl resin, epoxy resin, phenolic resin, polyamide resin, and/or polyimide resin.

In an embodiment, a modulus of the first encapsulating organic layer OL1 may be lower than the modulus of the second encapsulating organic layer OL2 and the modulus of the third encapsulating organic layer OL3. In addition, a modulus of the fourth encapsulating organic layer OL4 may be lower than the modulus of the second encapsulating organic layer OL2 and the modulus of the third encapsulating organic layer OL3.

In an embodiment, the touch electrode layer SENL is disposed on the encapsulation layer ENC. The touch electrode layer SENL may include touch electrodes TE and RE, touch connection electrodes BE, and touch wirings TL. The touch electrodes TE and RE may include driving electrodes TE and sensing electrodes RE.

In an embodiment, a third buffer layer BF3 may be disposed on the encapsulation layer ENC. The third buffer layer BF3 may be made of a silicon nitride layer, a silicon oxynitride layer, a silicon oxide layer, a titanium oxide layer, and/or an aluminum oxide layer.

In an embodiment, the touch connection electrodes BE and the touch wirings TL may be disposed on the third buffer layer BF3. The touch connection electrodes BE may be disposed in the first display area DA1 and the second display area DA2. The touch connection electrodes BE may be electrodes for connecting the driving electrodes TE adjacent to each other at intersections of the driving electrodes TE and the sensing electrodes RE. The touch wirings TL may be disposed in the third display area DA3 and the non-display area NDA. The touch wirings TL may be disposed between the first through third emission areas EA1_3, EA2_3 and EA3_3, respectively, in the third display area DA3. Each of the touch wirings TL may be electrically connected to some of the driving electrodes TE and/or some of the sensing electrodes RE. Each of the touch connection electrodes BE and the touch wirings TL may be a single layer of molybdenum (Mo), titanium (Ti), copper (Cu) or aluminum (Al) and/or may be a stacked structure (Ti/Al/Ti) of aluminum and titanium, a stacked structure (ITO/AV/ITO) of aluminum and indium tin oxide, an APC alloy, and/or a stacked structure (ITO/APC/ITO) of an APC alloy and indium tin oxide.

In an embodiment, a first touch insulating layer TINS1 may be disposed on the touch connection electrodes BE and the touch wirings TL. The first touch insulating layer TINS1 may be made of a silicon nitride layer, a silicon oxynitride layer, a silicon oxide layer, a titanium oxide layer, and/or an aluminum oxide layer.

In an embodiment, the driving electrodes TE and the sensing electrodes RE may be disposed on the first touch insulating layer TINS1. The driving electrodes TE and the sensing electrodes RE may be disposed in the first display area DA1 and the second display area DA2. The driving electrodes TE and the sensing electrodes RE may be disposed between the first through fourth emission areas EA1 through EA4, respectively, in the first display area DA1. Therefore, it is possible to prevent light emitted from the first through fourth emission areas EA1 through EA4, respectively, from being blocked by the driving electrodes TE and the sensing electrodes RE and thus prevent or reduce a decrease in the luminance of the light. In addition, the driving electrodes TE and the sensing electrodes RE may be disposed between the first through third emission areas EA1_2, EA2_2 and EA3_2, respectively, in the second display area DA2. Therefore, it is possible to prevent light emitted from the first through third emission areas EA1_2, EA2_2 and EA3_2, respectively, from being blocked by the driving electrodes TE and the sensing electrodes RE and thus prevent and/or reduce a decrease in the luminance of the light.

In an embodiment, the driving electrodes TE neighboring each other at the intersections of the driving electrodes TE and the sensing electrodes RE may be connected to a touch connection electrode BE through touch contact holes TCNT1 penetrating the first touch insulating layer TINS1. Each of the driving electrodes TE and the sensing electrodes RE may be a single layer of molybdenum (Mo), titanium (Ti), copper (Cu) and/or aluminum (Al) and/or may be a stacked structure (Ti/Al/Ti) of aluminum and titanium, a stacked structure (ITO/Al/ITO) of aluminum and indium tin oxide, an APC alloy, and/or a stacked structure (ITO/APC/ITO) of an APC alloy and indium tin oxide.

In an embodiment, a second touch insulating layer TINS2 may be disposed on the driving electrodes TE and the sensing electrodes RE. The second touch insulating layer TINS2 may be an organic layer such as acryl resin, epoxy resin, phenolic resin, polyamide resin, and/or polyimide resin.

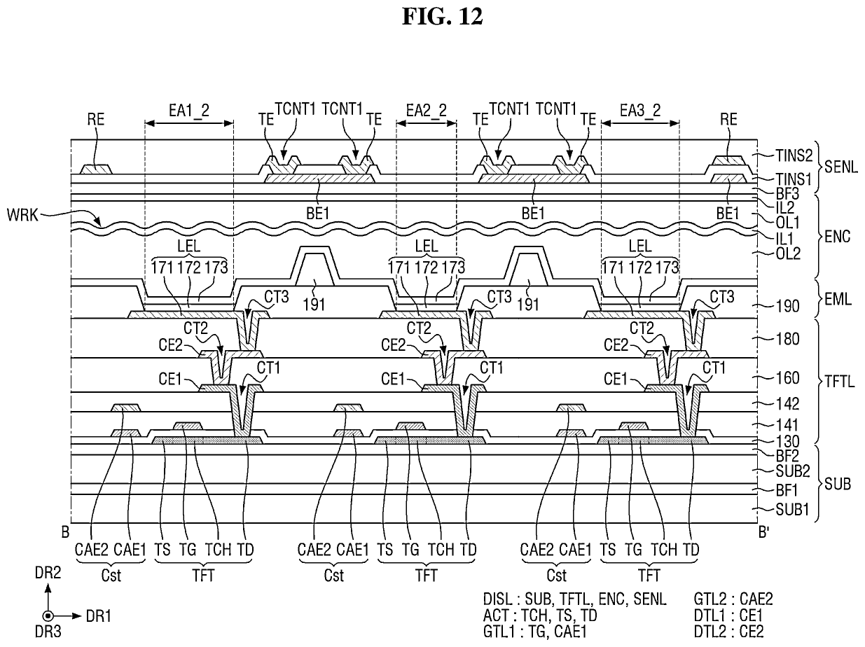

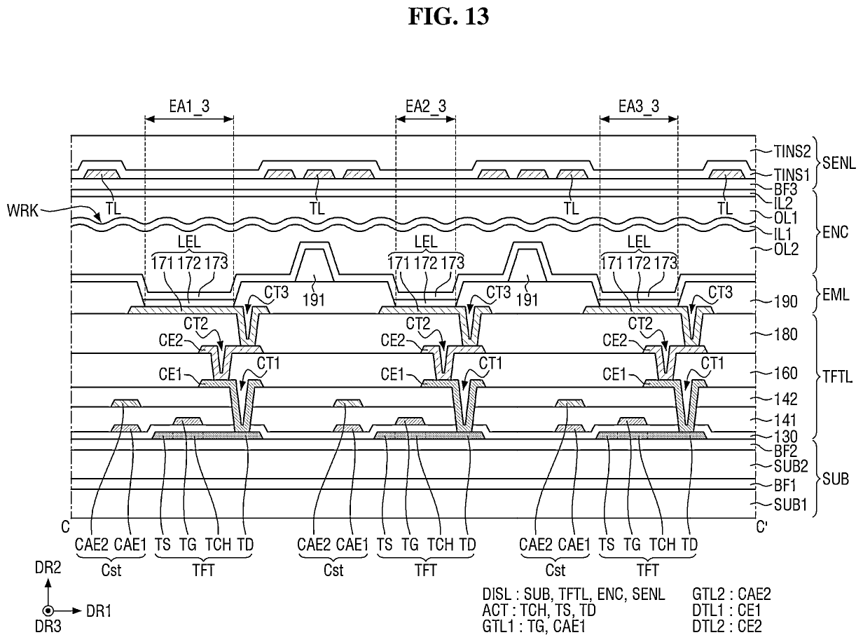

FIG. 12 is a cross-sectional view of an example of the display panel 100 taken along line B-B′ of FIG. 6, according to an embodiment. FIG. 13 is a cross-sectional view of an example of the display panel 100 taken along line C-C′ of FIG. 7, according to an embodiment.

The embodiment of FIGS. 12 and 13 is different from the embodiment of FIGS. 9 and 10 in that the third encapsulating organic layer OL3 and the fourth encapsulating organic layer OL4 are omitted.

In an embodiment, referring to FIGS. 12 and 13, since the third encapsulating organic layer OL3 is omitted, the second encapsulating inorganic layer IL2 may be disposed on the first encapsulating organic layer OL1. That is, the second encapsulating inorganic layer IL2 may directly contact the first encapsulating organic layer OL1. In this case, a wrinkle portion WRK may be formed only at a boundary between the second encapsulating organic layer OL2 and the first encapsulating inorganic layer IL1.

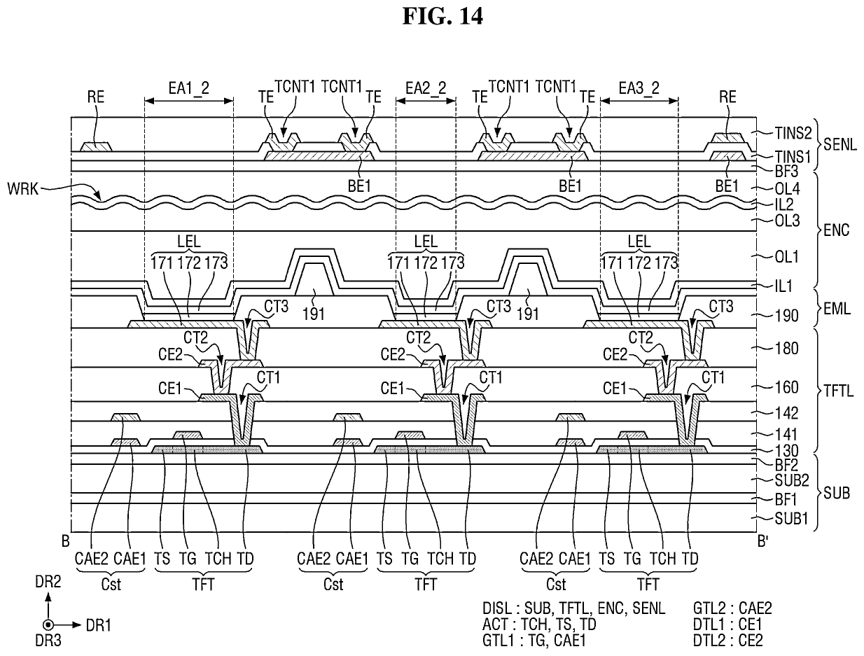

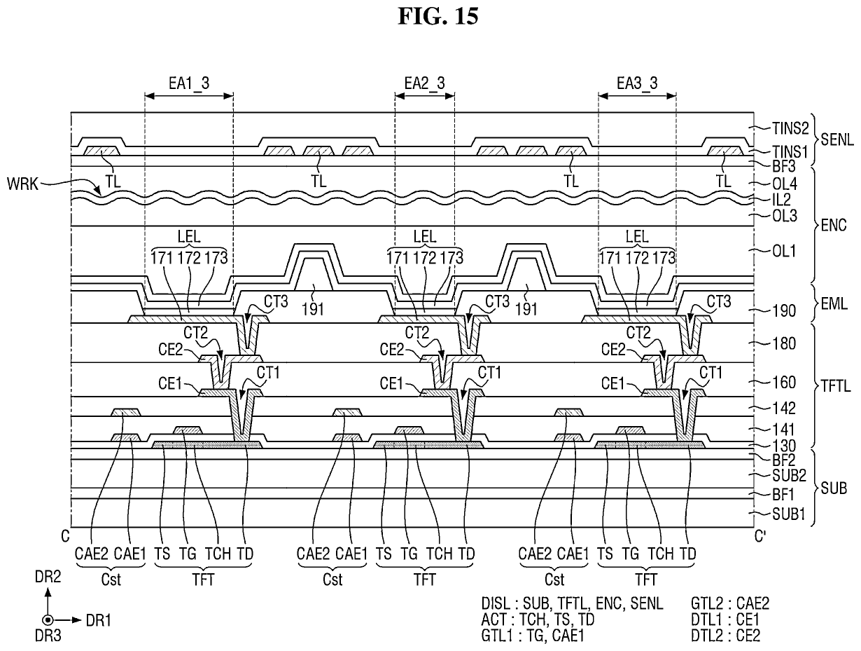

FIG. 14 is a cross-sectional view of an example of the display panel 100 taken along line B-B′ of FIG. 6, according to an embodiment. FIG. 15 is a cross-sectional view of an example of the display panel 100 taken along line C-C′ of FIG. 7, according to an embodiment.

The embodiment of FIGS. 14 and 15 is different from the embodiment of FIGS. 9 and 10 in that the second encapsulating organic layer OL2 is omitted.

In an embodiment, referring to FIGS. 14 and 15, since the second encapsulating organic layer OL2 is omitted, the first encapsulating organic layer OL1 may be disposed on the first encapsulating inorganic layer IL1. That is, the first encapsulating organic layer OL1 may directly contact the first encapsulating inorganic layer IL1. In this case, a wrinkle portion WRK may be formed only at a boundary between the third encapsulating organic layer OL3 and the second encapsulating inorganic layer IL2.

FIG. 16 is a layout view illustrating, in detail, first through third display areas DA1 through DA3, respectively, and a non-display area NDA disposed in a first corner portion CS1 of a display panel 100 according to an embodiment. FIG. 17 is a layout view of an example of the second display area DA2 of FIG. 16 according to an embodiment.

The embodiment of FIGS. 16 and 17 is different from the embodiment of FIGS. 4 and 6 in that the second display area DA2 includes cutout patterns CP and cutout portions CG.

In an embodiment, referring to FIGS. 16 and 17, the cutout patterns CP may be formed by various processes, such as cutting part or all of the display panel 100 using a laser or etching the display panel 100 using an etching process. For example, the cutout patterns CP may be formed by etching a thin-film transistor layer TFTL (see FIG. 9) and a light emitting element layer EML (see FIG. 9) except for a substrate SUB of the display panel 100.

In an embodiment, an end of each of the cutout patterns CP may be connected to the third display area DA3, and the other end may be connected to the non-display area NDA. The cutout patterns CP adjacent to each other may be spaced apart by a cutout portion CG. A space may be provided between the adjacent cutout patterns CP by the cutout portion CG. Therefore, even if the first corner portion CS1 has a double curvature, since the first corner portion CS1 can be stretched and contracted, the strain applied to the first corner portion CS1 can be reduced by the cutout portions CG.

In an embodiment, second pixels PX2 may be disposed on the cutout patterns CP. Each of the second pixels PX2 may include first through third emission areas EA1_2, EA2_2, and EA3_2, respectively.

In an embodiment, a dam DAM may be disposed along edges of the cutout patterns CP. The dam DAM may surround the second pixels PX2. The dam DAM2 may be a structure for preventing the overflowing of a first encapsulating organic layer OL1 disposed in the second display area DA2.

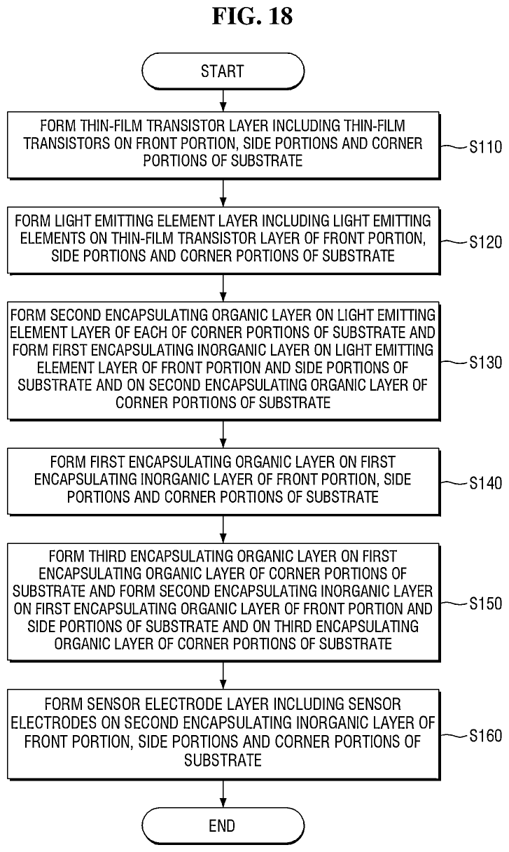

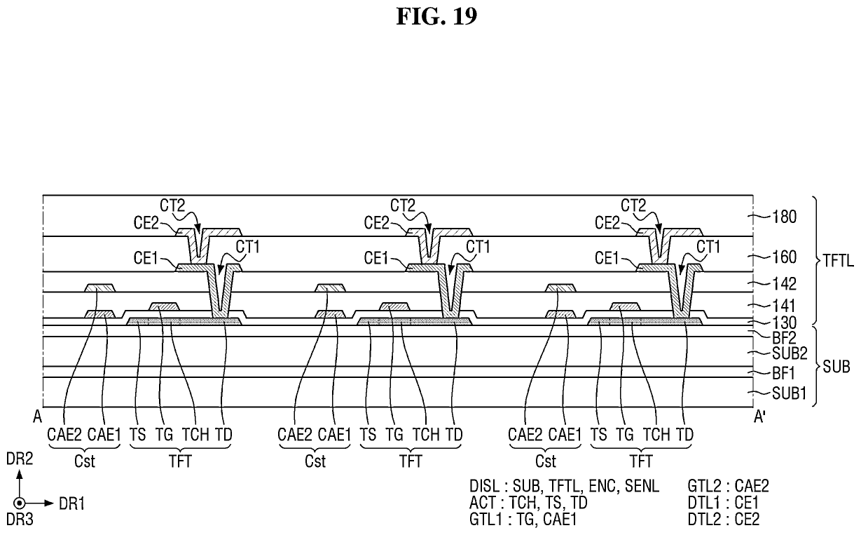

FIG. 18 is a flowchart illustrating a method of fabricating a display device according to an embodiment. FIGS. 19 through 30 are cross-sectional views for explaining the method of fabricating the display device according to the embodiment.

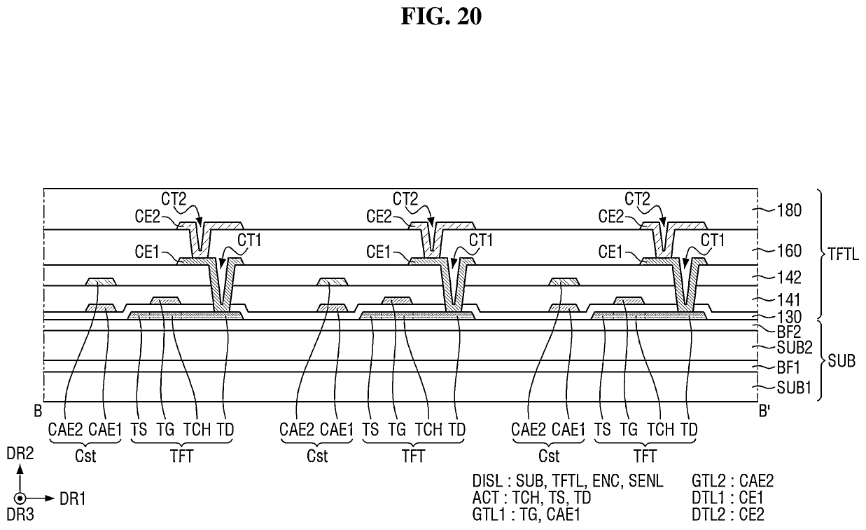

FIGS. 19, 21, 23, 25, 27, and 29 illustrate cross sections of a display panel taken along line A-A′ of FIG. 5. FIGS. 20, 22, 24, 26, 28 and 30 illustrate cross sections of the display panel taken along line B-B′ of FIG. 6.

First, in an embodiment and as illustrated in FIGS. 19 and 20, a thin-film transistor layer TFTL including thin-film transistors TFT and capacitors Cst may be formed on a front portion FS, side portions SS1 through SS4 and corner portions CS1 through CS4 of a substrate SUB. That is, the thin-film transistor layer TFTL may be formed in a first display area DA1, a second display area DA2, and a third display area DA3 (operation S110 in FIG. 18).

In an embodiment, an active layer ACT including a channel layer TCH, a first electrode TS and a second electrode TD of each of the thin-film transistors TFT may be formed on the substrate SUB by using a photolithography process. The active layer ACT may include a silicon semiconductor such as polycrystalline silicon, monocrystalline silicon, low-temperature polycrystalline silicon and/or amorphous silicon and/or may include an oxide semiconductor.

Next, in an embodiment, a gate insulating layer 130 may be formed to cover the active layer ACT. The gate insulating layer 130 may be made of an inorganic layer, for example, a silicon nitride layer, a silicon oxynitride layer, a silicon oxide layer, a titanium oxide layer, and/or an aluminum oxide layer.

Next, in an embodiment, a first gate metal layer GTL1 including a gate electrode TG of each of the thin-film transistors TFT and a first capacitor electrode CAE1 of each of the capacitors Cst may be formed on the gate insulating layer 130 by using a photolithography process. The first gate metal layer GTL1 may be a single layer or a multilayer made of any one or more of molybdenum (Mo), aluminum (Al), chromium (Cr), gold (Au), titanium (Ti), nickel (Ni), neodymium (Nd), copper (Cu), and/or alloys thereof.

Next, in an embodiment, the first electrode TS and the second electrode TD of each of the thin-film transistors TFT are doped with ions or impurities by using the first gate metal layer GTL1 as a mask. Accordingly, the first electrode TS and the second electrode TD of each of the thin-film transistors TFT may have conductivity.

Next, in an embodiment, a first interlayer insulating layer 141 may be formed to cover the first gate metal layer GTL1. The first interlayer insulating layer 141 may be made of an inorganic layer, for example, a silicon nitride layer, a silicon oxynitride layer, a silicon oxide layer, a titanium oxide layer, and/or an aluminum oxide layer.

Next, in an embodiment, a second gate metal layer GTL2 including a second capacitor electrode CAE2 of each capacitor Cst may be formed on the first interlayer insulating layer 141 by using a photolithography process. The second gate metal layer GTL2 may be a single layer or a multilayer made of any one or more of molybdenum (Mo), aluminum (Al), chromium (Cr), gold (Au), titanium (Ti), nickel (Ni), neodymium (Nd), copper (Cu), and/or alloys thereof.

Next, in an embodiment, a second interlayer insulating layer 142 may be formed to cover the second gate metal layer GTL2. The second interlayer insulating layer 142 may be made of an inorganic layer, for example, a silicon nitride layer, a silicon oxynitride layer, a silicon oxide layer, a titanium oxide layer, and/or an aluminum oxide layer.

Next, in an embodiment, the gate insulating layer 130, the first interlayer insulating layer 141, and the second interlayer insulating layer 142 may be etched to form first contact holes CT1 exposing the second electrodes TD of the thin-film transistors TFT.

Next, in an embodiment, a first data metal layer DTL1 including first connection electrodes CE1 may be formed on the second interlayer insulating layer 142 by using a photolithography process. Each of the first connection electrodes CE1 is connected to the second electrode TD of a thin-film transistor TFT through a first contact hole CT1. The first data metal layer DTL1 may be a single layer or a multilayer made of any one or more of molybdenum (Mo), aluminum (Al), chromium (Cr), gold (Au), titanium (Ti), nickel (Ni), neodymium (Nd), copper (Cu), and/or alloys thereof.

Next, in an embodiment, a first planarization layer 160 may be formed to cover the first data metal layer DTL1. The first planarization layer 160 may be made of an organic layer such as acryl resin, epoxy resin, phenolic resin, polyamide resin, and/or polyimide resin.

Next, in an embodiment, the first planarization layer 160 may be etched to form second contact holes CT2 exposing the first connection electrodes CE1.

Next, in an embodiment, a second data metal layer DTL2 including second connection electrodes CE2 may be formed on the first planarization layer 160 by using a photolithography process. Each of the second connection electrodes CE2 may be connected to a first connection electrode CE1 through a second contact hole CT2. The second data metal layer DTL2 may be a single layer or a multilayer made of any one or more of molybdenum (Mo), aluminum (Al), chromium (Cr), gold (Au), titanium (Ti), nickel (Ni), neodymium (Nd), copper (Cu), and/or alloys thereof.

Next, in an embodiment, a second planarization layer 180 may be formed to cover the second data metal layer DTL2. The second planarization layer 180 may be made of an organic layer such as acryl resin, epoxy resin, phenolic resin, polyamide resin, and/or polyimide resin.

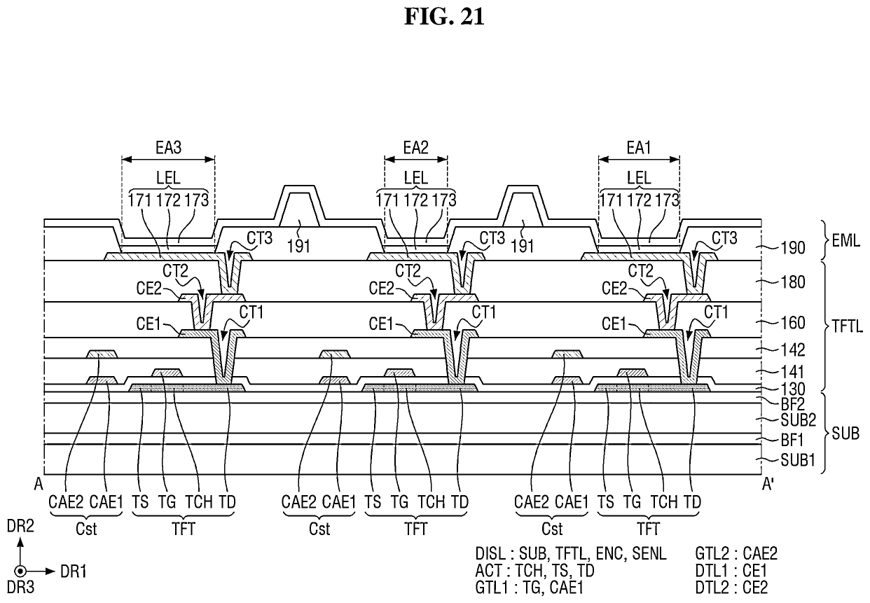

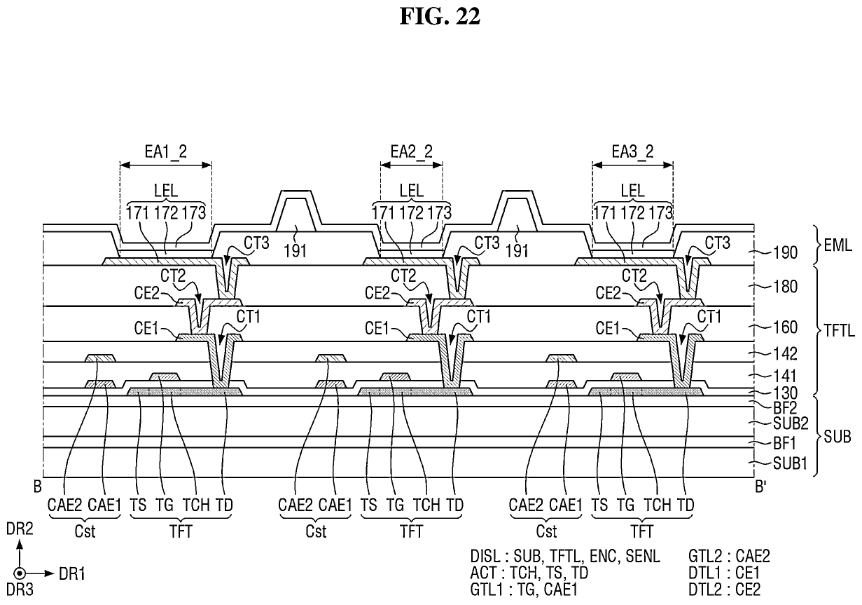

Second, in an embodiment and as illustrated in FIGS. 21 and 22, a light emitting element layer EML including light emitting elements LEL and a bank 190 may be formed on the thin-film transistor layer TFTL of the front portion FS, the side portions SS1 through SS4 and the corner portions CS1 through CS4 of the substrate SUB. That is, the light emitting element layer EML may be formed in the first display area DA1, the second display area DA2, and the third display area DA3 (operation S120 in FIG. 18).

In an embodiment, the second planarization layer 180 may be etched to form third contact holes CT3 exposing the second connection electrodes CE2.

Next, in an embodiment, first electrodes 171 of the light emitting elements LEL may be formed on the second planarization layer 180 by using a photolithography process. The first electrode 171 of each of the light emitting elements LEL may be connected to a second connection electrode CE2 through a third contact hole CT3. The first electrode 171 of each of the light emitting elements LEL may be made of a metal material having high reflectivity, such as a stacked structure (Ti/Al/Ti) of aluminum and titanium, a stacked structure (ITO/AI/ITO) of aluminum and indium tin oxide, an APC alloy, and/or a stacked structure (ITO/APC/ITO) of an APC alloy and indium tin oxide. The APC alloy is an alloy of silver (Ag), palladium (Pd), and copper (Cu).

Next, in an embodiment, the bank 190 may be formed to cover edges of the first electrode 171 of each of the light emitting elements LEL by using a photolithography process. The bank 190 may be made of an organic layer such as acryl resin, epoxy resin, phenolic resin, polyamide resin, and/or polyimide resin.

Next, in an embodiment, a light emitting layer 172 may be formed by evaporation on each of the first electrodes 171 exposed without being covered by the bank 190. A light emitting layer emitting light of a first color may be deposited in a first emission area EA1 of each first pixel PX1, a first emission area EA1_2 of each second pixel PX2, and a first emission area EA1_3 of each third pixel PX3, all of which emit light of the first color. In addition, a light emitting layer emitting light of a second color may be deposited in a second emission area EA2 of each first pixel PX1, a second emission area EA2_2 of each second pixel PX2, and a second emission area EA2_3 of each third pixel PX3, all of which emit light of the second color. In addition, a light emitting layer emitting light of a third color may be deposited in a third emission area EA3 of each first pixel PX1, a third emission area EA3_2 of each second pixel PX2, and a third emission area EA3_3 of each third pixel PX3, all of which emit light of the third color.

Next, in an embodiment, a second electrode 173 may be formed on the light emitting layers 172 and the bank 190. The second electrode 173 may be commonly disposed over the first display area DA1, the second display area DA2, and the third display area DA3 as a whole. The second electrode 173 may be made of a transparent conductive material (TCO) capable of transmitting light, such as indium tin oxide (ITO) and/or indium zinc oxide (IZO), and/or a semi-transmissive conductive material such as magnesium (Mg), silver (Ag) and/or an alloy of Mg and Ag.

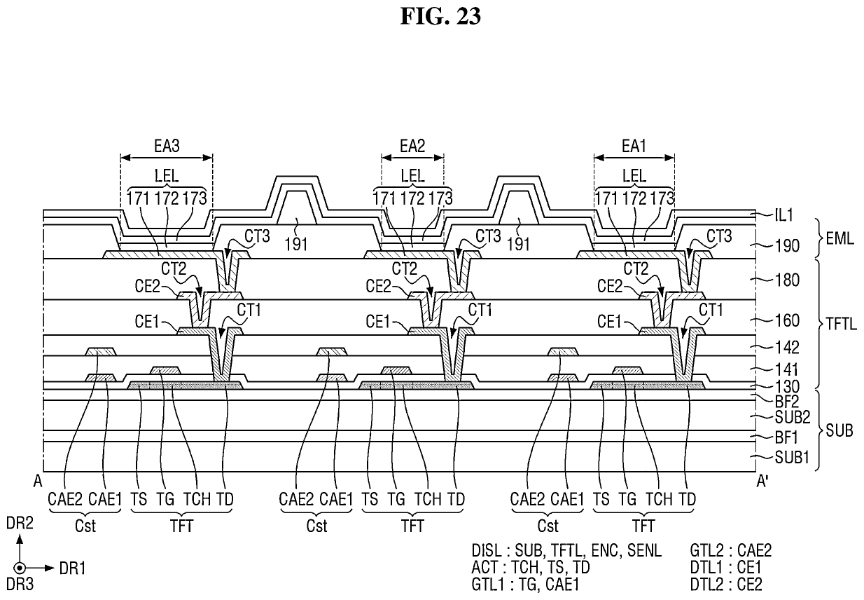

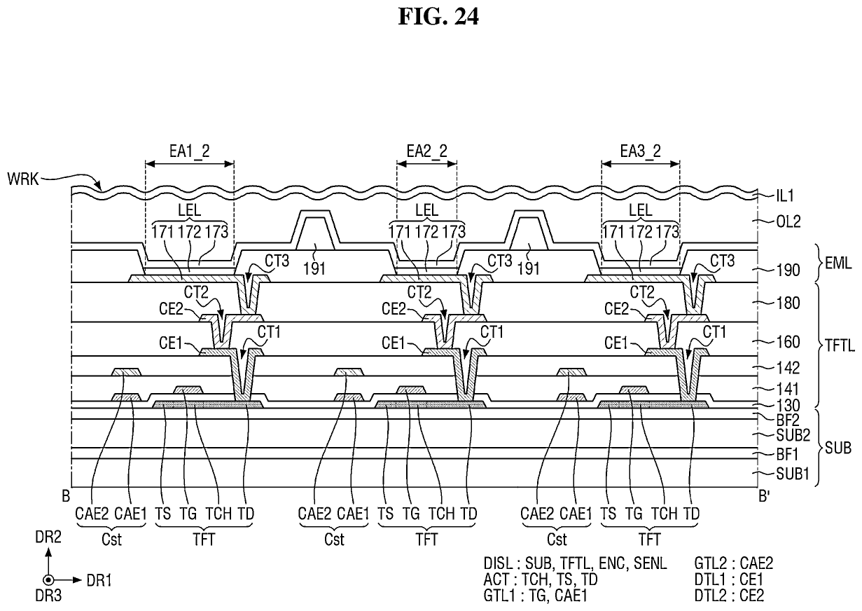

Third, in an embodiment, as illustrated in FIGS. 23 and 24, a second encapsulating organic layer OL2 may be formed on the second electrode 173 of the light emitting element layer EML of the corner portions CS1 through CS4 of the substrate SUB, and a first encapsulating inorganic layer IL1 is formed on the second electrode 173 of the light emitting element layer EML of the front portion FS and the side portions SS1 through SS4 of the substrate SUB and on the second encapsulating organic layer OL2 of the corner portions CS1 through CS4 (operation S130 in FIG. 18).

In an embodiment, the second encapsulating organic layer OL2 may be formed in the second display area DA2 and the third display area DA3, but may not be formed in the first display area DA1. The second encapsulating organic layer OL2 may be made of hexamethyldisiloxane (HMDSO).

In an embodiment, the first encapsulating inorganic layer IL1 may be formed in the first display area DA1, the second display area DA2, and the third display area DA3. The first encapsulating inorganic layer IL1 may be formed on the second electrode 173 of the light emitting element layer EML in the first display area DA1. On the other hand, the first encapsulating inorganic layer IL1 may be formed on the second encapsulating organic layer OL2 in the second display area DA2 and the third display area DA3. The first encapsulating inorganic layer IL1 may be a multilayer in which one or more inorganic layers selected from a silicon nitride layer, a silicon oxynitride layer, a silicon oxide layer, a titanium oxide layer, and/or an aluminum oxide layer are alternately stacked.

In an embodiment, a modulus of the second encapsulating organic layer OL2 may be smaller than a modulus of the first encapsulating inorganic layer IL1 by at least about 300 MPa. When a material layer having a high modulus is formed on a material layer having a low modulus, a wrinkle portion WRK may be formed between the two layers due to a difference between the moduli of the two layers. That is, when the second encapsulating organic layer OL2 and the first encapsulating inorganic layer IL1 having different moduli are formed without a special process, the wrinkle portion WRK may be naturally formed at a boundary between the second encapsulating organic layer OL2 and the first encapsulating inorganic layer IL1 as illustrated in FIGS. 23 and 24 due to thin-film stress.

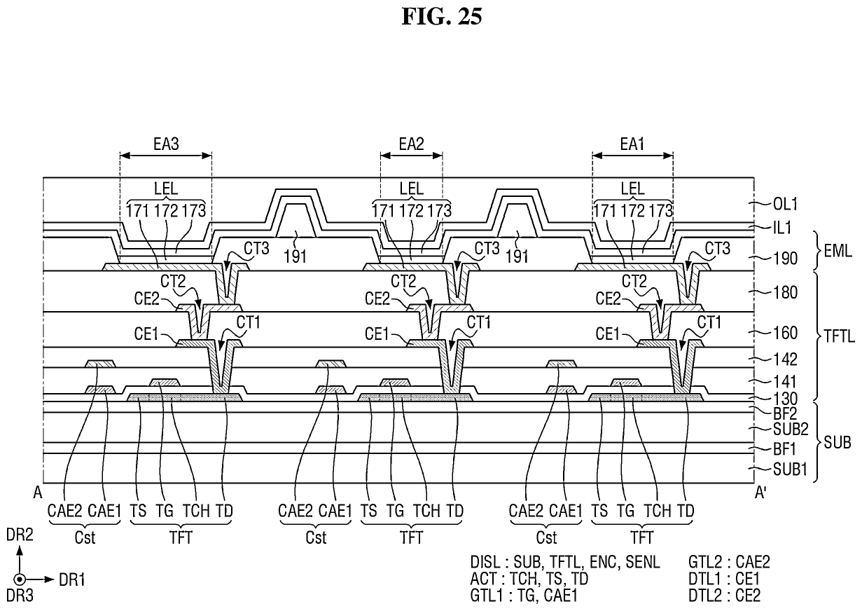

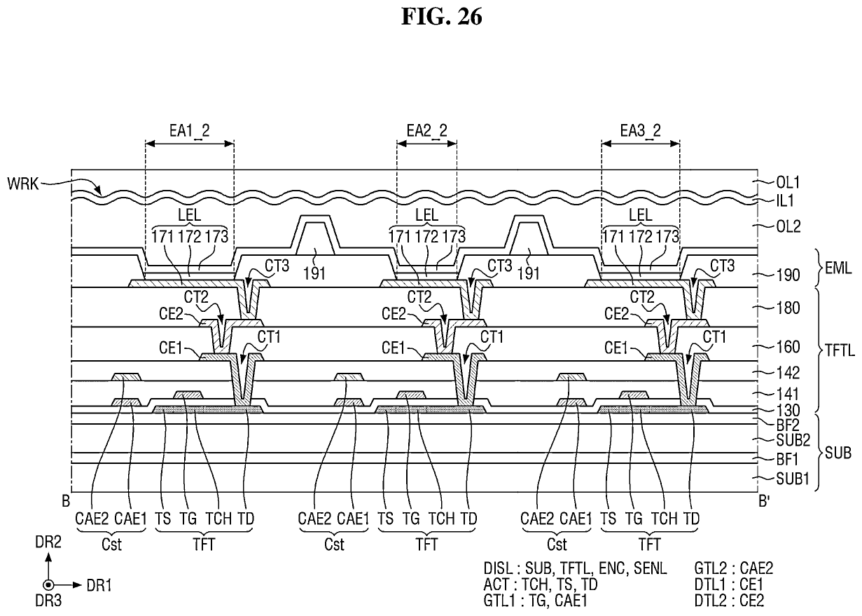

Fourth, in an embodiment, as illustrated in FIGS. 25 and 26, a first encapsulating organic layer OL1 may be formed on the first encapsulating inorganic layer IL1 on the second electrode 173 of the light emitting element layer EML of the front portion FS and the side portions SS1 through SS4 of the substrate SUB and may be formed on the first encapsulating inorganic layer IL1 of the corner portions CS1 through CS4 (operation 140 in FIG. 18).

In an embodiment, the first encapsulating organic layer OL1 may be formed in the first display area DA1, the second display area DA2, and the third display area DA3. The first encapsulating organic layer OL1 may be made of a monomer.

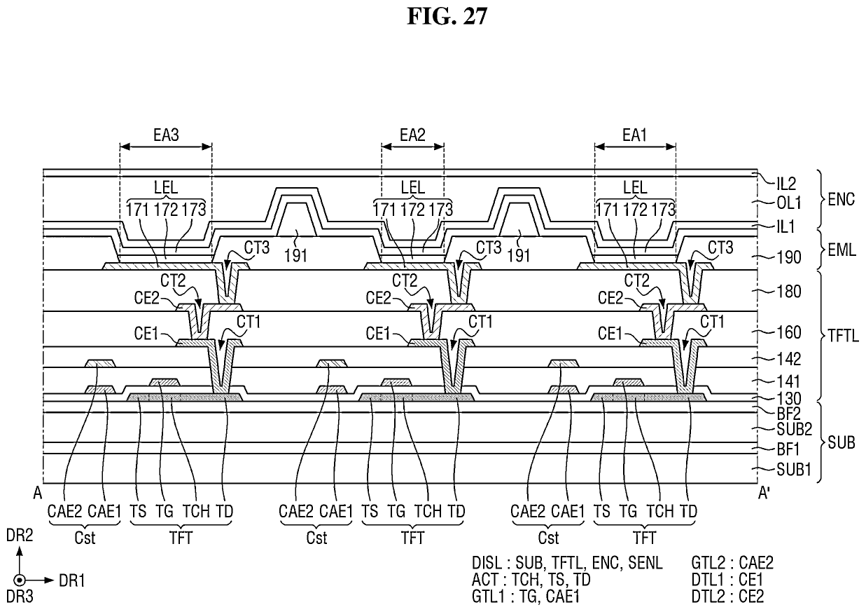

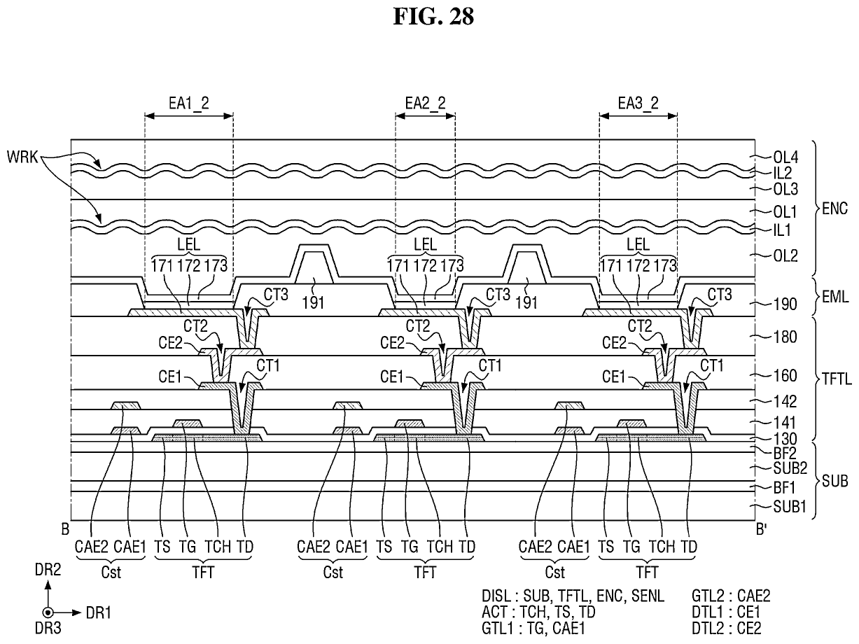

Fifth, in an embodiment, as illustrated in FIGS. 27 and 28, a third encapsulating organic layer OL3 may be formed on the first encapsulating organic layer OL1 of the corner portions CS1 through CS4 of the substrate SUB, and a second encapsulating inorganic layer IL2 may be formed on the first encapsulating organic layer OL1 of the front portion FS and the side portions SS1 through SS4 of the substrate SUB and on the third encapsulating organic layer OL3 of the corner portions CS1 through CS4 (operation S150 in FIG. 18).

In an embodiment, the third encapsulating organic layer OL3 may be formed in the second display area DA2 and the third display area DA3, but may not be formed in the first display area DA1. The third encapsulating organic layer OL3 may be made of hexamethyldisiloxane (HMDSO).

In an embodiment, the second encapsulating inorganic layer IL2 may be formed in the first display area DA1, the second display area DA2, and the third display area DA3. The second encapsulating inorganic layer IL2 may be formed on the first encapsulating organic layer OL1 in the first display area DA1. On the other hand, the second encapsulating inorganic layer IL2 may be formed on the third encapsulating organic layer OL3 in the second display area DA2 and the third display area DA3. The first encapsulating inorganic layer IL1 may be a multilayer in which one or more inorganic layers selected from a silicon nitride layer, a silicon oxynitride layer, a silicon oxide layer, a titanium oxide layer, and/or an aluminum oxide layer may be alternately stacked.

In an embodiment, a modulus of the third encapsulating organic layer OL3 may be smaller than a modulus of the second encapsulating inorganic layer IL2 by at least about 300 MPa. When a material layer having a high modulus is formed on a material layer having a low modulus, a wrinkle portion WRK may be formed between the two layers due to a difference between the moduli of the two layers. That is, when the third encapsulating organic layer OL3 and the second encapsulating inorganic layer IL2 having different moduli are formed without a special process, the wrinkle portion WRK may be naturally formed at a boundary between the third encapsulating organic layer OL3 and the second encapsulating inorganic layer IL2 as illustrated in FIGS. 27 and 28 due to thin-film stress.

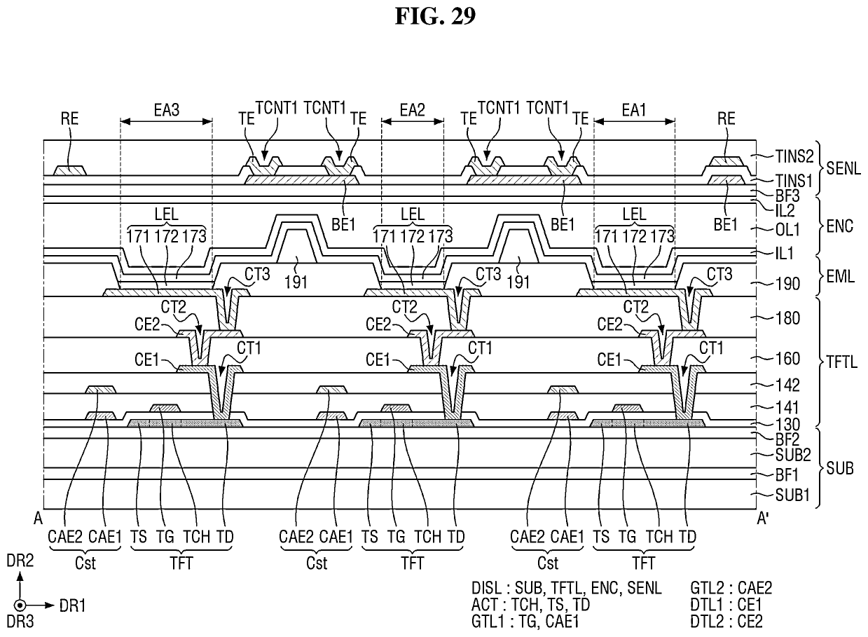

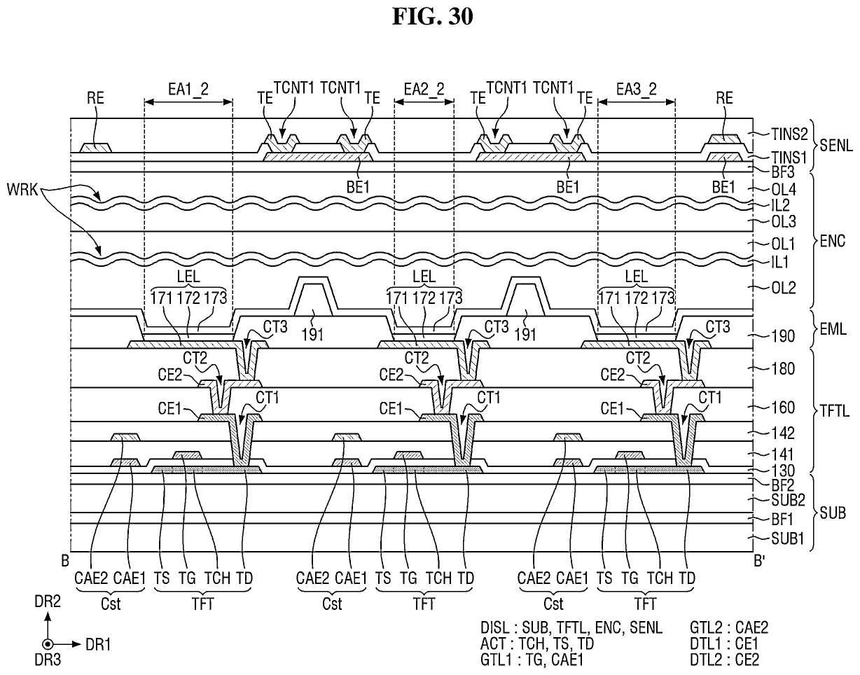

Sixth, in an embodiment, as illustrated in FIGS. 29 and 30, a touch electrode layer SENL is formed on the second encapsulating inorganic layer IL2 of the front portion FS, the side portions SS1 through SS4 and the corner portions CS1 through CS4 of the substrate SUB (operation S160 in FIG. 18).

In an embodiment, a third buffer layer BF3 may be formed on the second encapsulating inorganic layer IL2. The third buffer layer BF3 may be made of a silicon nitride layer, a silicon oxynitride layer, a silicon oxide layer, a titanium oxide layer, and/or an aluminum oxide layer.

Next, in an embodiment, touch connection electrodes BE and touch wirings TL may be formed on the third buffer layer BF3. The touch connection electrodes BE may be formed in the first display area DA1 and the second display area DA2, and the touch wirings TL may be formed in the third display area DA3 and the non-display area NDA. Each of the touch connection electrodes BE and the touch wirings TL may be a single layer of molybdenum (Mo), titanium (Ti), copper (Cu) and/or aluminum (Al) and/or may be a stacked structure (Ti/Al/Ti) of aluminum and titanium, a stacked structure (ITO/AI/ITO) of aluminum and indium tin oxide, an APC alloy, and/or a stacked structure (ITO/APC/ITO) of an APC alloy and indium tin oxide.

Next, in an embodiment, a first touch insulating layer TINS1 may be formed on the touch connection electrodes BE and the touch wirings TL. The first touch insulating layer TINS1 may be made of a silicon nitride layer, a silicon oxynitride layer, a silicon oxide layer, a titanium oxide layer, and/or an aluminum oxide layer.

Next, in an embodiment, the first touch insulating layer TINS1 may be etched to form touch contact holes TCNT1.

Next, in an embodiment, driving electrodes TE and sensing electrodes RE may be formed on the first touch insulating layer TINS1. Each of the driving electrodes TE may be connected to a touch connection electrode BE through a touch contact hole TCNT1. Therefore, the driving electrodes TE and the sensing electrodes RE may cross each other at intersections of the driving electrodes TE and the sensing electrodes RE while being electrically insulated from each other. Each of the driving electrodes TE and the sensing electrodes RE may be a single layer of molybdenum (Mo), titanium (Ti), copper (Cu) and/or aluminum (Al) and/or may be a stacked structure (Ti/Al/Ti) of aluminum and titanium, a stacked structure (ITO/AI/ITO) of aluminum and indium tin oxide, an APC alloy, and/or a stacked structure (ITO/APC/ITO) of an APC alloy and indium tin oxide.

Next, in an embodiment, a second touch insulating layer TINS may be formed on the driving electrodes TE and the sensing electrodes RE. The second touch insulating layer TINS2 may be an organic layer such as acryl resin, epoxy resin, phenolic resin, polyamide resin, and/or polyimide resin.

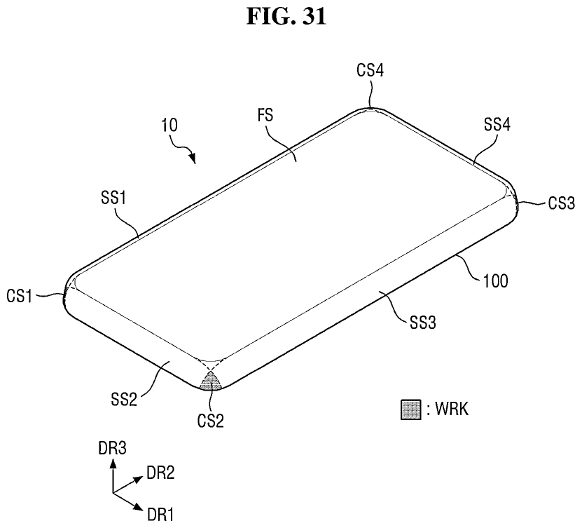

FIG. 31 illustrates a display device having a wrinkle portion WRK according to an embodiment.

Referring to FIG. 31, in an embodiment, the wrinkle portion WRK formed at a boundary between a second encapsulating organic layer OL2 and a first encapsulating inorganic layer IL1 and/or a boundary between a third encapsulating organic layer OL3 and a second encapsulating inorganic layer IL2 may be formed in a plurality of corner portions CS1 through CS4 which are double-curvature areas. In this case, the wrinkle portion WRK may reduce the strain applied to an encapsulation layer ENC in each of the corner portions CS1 through CS4.

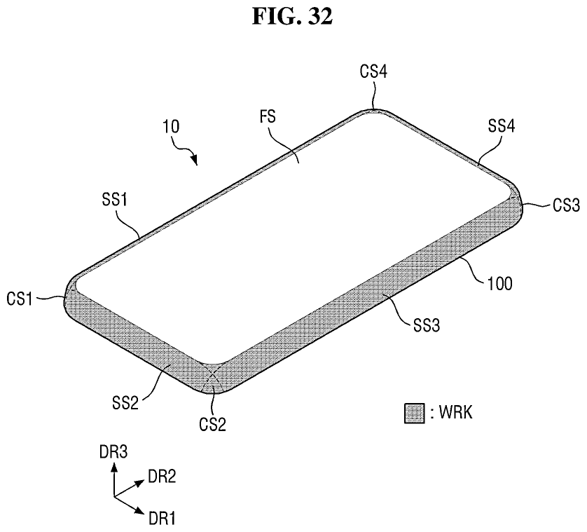

FIG. 32 illustrates a display device having a wrinkle portion WRK according to an embodiment.

Referring to FIG. 32, in an embodiment, the wrinkle portion WRK formed at a boundary between a second encapsulating organic layer OL2 and a first encapsulating inorganic layer IL1 and/or a boundary between a third encapsulating organic layer OL3 and a second encapsulating inorganic layer IL2 may be formed not only in a plurality of corner portions CS1 through CS4 which are double-curvature areas but also in a plurality of side portions SS1 through SS4 bent with a predetermined curvature. In this case, the wrinkle portion WRK may reduce the bending stress applied to an encapsulation layer ENC in each of the side portions SS1 through SS4.

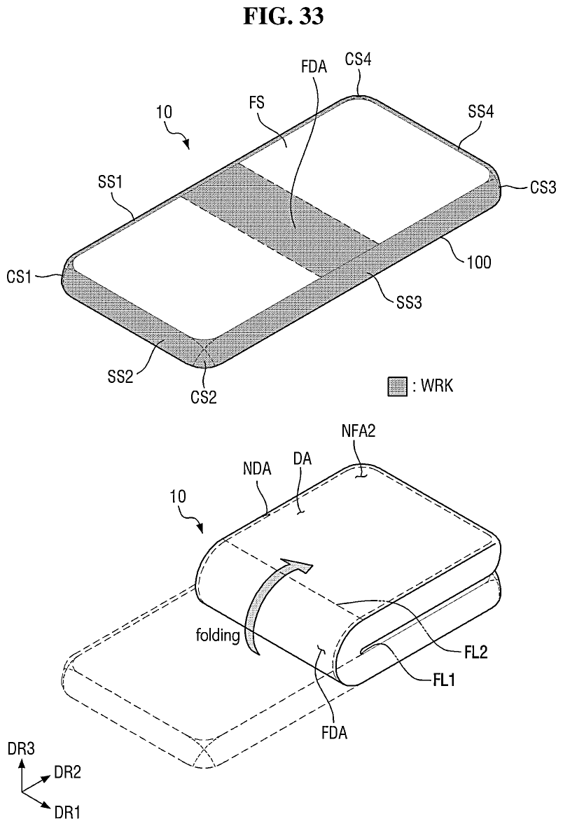

FIG. 33 illustrates a display device having a wrinkle portion WRK according to an embodiment.

Referring to FIG. 33, in an embodiment, the wrinkle portion WRK formed at a boundary between a second encapsulating organic layer OL2 and a first encapsulating inorganic layer IL1 and/or a boundary between a third encapsulating organic layer OL3 and a second encapsulating inorganic layer IL2 may be formed not only in a plurality of corner portions CS1 through CS4 which may be double-curvature areas and a plurality of side portions SS1 through SS4 bent with a predetermined curvature, but also in a folding area FDA that can be bent or folded. In this case, the wrinkle portion WRK may reduce the folding stress applied to an encapsulation layer ENC in the folding area FDA.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims. Moreover, the embodiments or parts of the embodiments may be combined in whole or in part without departing from the scope of the invention.

What is claimed is:

1. A display device comprising:
a substrate comprising a front portion, a first side portion extending from a first side of the front portion, a second side portion extending from a second side of the front portion, and a corner portion disposed between the first side portion and the second side portion;
a plurality of light emitting elements disposed on the front portion and the corner portion of the substrate and each of the plurality of light emitting elements comprising a first electrode, a light emitting layer and a second electrode;
a first encapsulating inorganic layer disposed on the second electrode of each of the plurality of light emitting elements located on the front portion of the substrate and on the corner portion of the substrate;
a first encapsulating organic layer disposed on the first encapsulating inorganic layer located on the front portion of the substrate and on the corner portion of the substrate;
a second encapsulating inorganic layer disposed on the first encapsulating organic layer located on the front portion of the substrate and on the corner portion of the substrate; and
a second encapsulating organic layer disposed between the second electrode of each of the plurality of light emitting elements and the first encapsulating inorganic layer located on the corner portion of the substrate.

2. The display device of claim 1, wherein a modulus of the second encapsulating organic layer is lower than a modulus of the first encapsulating inorganic layer.

3. The display device of claim 1, wherein the first encapsulating organic layer comprises a monomer, and the second encapsulating organic layer comprises hexamethyldisiloxane (HMDSO).

4. The display device of claim 1, wherein a wrinkle portion is formed on the corner portion due to a difference between the modulus of the second encapsulating organic layer and the modulus of the first encapsulating inorganic layer.

5. The display device of claim 1, further comprising a third encapsulating organic layer disposed between the first encapsulating organic layer and the second encapsulating inorganic layer on the corner portion of the substrate.

6. The display device of claim 5, wherein a modulus of the third encapsulating organic layer is lower than the modulus of the second encapsulating inorganic layer.

7. The display device of claim 5, wherein the third encapsulating organic layer is made of the same material as the second encapsulating organic layer.

8. The display device of claim 5, wherein the third encapsulating organic layer comprises hexamethyldisiloxane (HMDSO).

9. The display device of claim 5, wherein a wrinkle portion is formed on the corner portion of the substrate due to a difference between the modulus of the third encapsulating organic layer and the modulus of the second encapsulating inorganic layer.

10. A display device comprising:
a substrate comprising a front portion, a first side portion extending from a first side of the front portion, a second side portion extending from a second side of the front portion, and a corner portion disposed between the first side portion and the second side portion;
a plurality of light emitting elements disposed on the front portion and the corner portion of the substrate, wherein each of the plurality of light emitting elements comprise a first electrode, a light emitting layer and a second electrode;
a first encapsulating inorganic layer disposed on the second electrode of each of the plurality of light emitting elements located on the front portion of the substrate and on the corner portion of the substrate;
a first encapsulating organic layer disposed on the first encapsulating inorganic layer located on the front portion of the substrate and on the corner portion of the substrate;
a second encapsulating inorganic layer disposed on the first encapsulating organic layer located on the front portion of the substrate and on the corner portion of the substrate; and
a second encapsulating organic layer disposed between the first encapsulating organic layer and the second encapsulating inorganic layer located on the corner portion of the substrate.

11. The display device of claim 10, wherein a modulus of the second encapsulating organic layer is lower than a modulus of the second encapsulating inorganic layer.

12. The display device of claim 10, wherein the second encapsulating organic layer comprises hexamethyldisiloxane (HMDSO).

13. The display device of claim 10, wherein a wrinkle portion is formed on the corner portion of the substrate due to a difference between the modulus of the second encapsulating organic layer and the modulus of the second encapsulating inorganic layer.

14. A method of fabricating a display device, the method comprising:
forming a thin-film transistor layer comprising a plurality of thin-film transistors located on a front portion and on a corner portion of a substrate among the front portion of the substrate, a first side portion extending from a first side of the front portion, a second side portion extending from a second side of the front portion, and the corner portion disposed between the first side portion and the second side portion;
forming a light emitting element layer disposed on the thin-film transistor layer of the front portion and located on the corner portion of the substrate and comprising a plurality of light emitting elements;
forming a second encapsulating organic layer on the light emitting element layer of the corner portion of the substrate;
forming a first encapsulating inorganic layer on the light emitting element layer of the front portion of the substrate and on the second encapsulating organic layer of the corner portion of the substrate; and
forming a first encapsulating organic layer on the first encapsulating inorganic layer of the front portion and the corner portion of the substrate,
wherein a modulus of the second encapsulating organic layer is lower than a modulus of the first encapsulating inorganic layer.

15. The method of claim 14, wherein the first encapsulating organic layer comprises a monomer, and the second encapsulating organic layer comprises hexamethyldisiloxane (HMDSO).

16. The method of claim 14, further comprising:
forming a third encapsulating organic layer on the first encapsulating organic layer of the corner portion of the substrate; and
forming a second encapsulating inorganic layer on the first encapsulating organic layer of the front portion of the substrate and on the third encapsulating organic layer of the corner portion of the substrate.

17. The method of claim 16, wherein the third encapsulating organic layer is made of the same material as the second encapsulating organic layer.

18. The method of claim 16, wherein a modulus of the third encapsulating organic layer is lower than the modulus of the second encapsulating inorganic layer.

19. The method of claim 16, wherein the third encapsulating organic layer comprises hexamethyldisiloxane (HMDSO).

20. The method of claim 16, further comprising forming a touch electrode layer comprising touch electrodes located on the second encapsulating inorganic layer of the front portion and on the corner portion of the substrate.
